(19) United States
(12) Patent Application Publication
(10) Pub. No.: US 2010/0108367 A1
(43) Pub. Date: May 6, 2010

(54) CURABLE RESIN COMPOSITION, COMPOSITE BODY, MOLDED BODY, LAMINATED BODY AND MULTILAYERED CIRCUIT BOARD

(76) Inventor: Tomoya Furushita, Kanagawa (JP)

Correspondence Address: BIRCH STEWART KOLASCH & BIRCH, PO BOX 747, FALLS CHURCH, VA, 22040-0747, US

(21) Appl. No.: 12/443,427

(22) PCT Filed: Sep. 28, 2007
(86) PCT No.: PCT/JP2007/069068

§ 371 Date: Mar. 27, 2009

(30) Foreign Application Priority Data
Sep. 29, 2006 (JP) 2006-269580

(51) Int. Cl. H05K 1/00; C08K 5/521; C08K 5/3492; B05D 3/02; B32B 27/32; B32B 27/36; B32B 27/06; B32B 5/00; B32B 37/00

(52) U.S. Cl. 174/258; 524/145; 524/101; 524/100; 427/389.9; 428/523; 428/483; 428/340; 156/60

(57) ABSTRACT

A curable resin composition comprising: 100 parts by weight of an alicyclic olefin polymer (A); from 1 to 100 parts by weight of a curing agent (B); from 10 to 50 parts by weight of a salt (C) of a basic nitrogen-containing compound with a phosphoric acid; and from 0.1 to 40 parts by weight of a condensed phosphate ester (D); of which phosphorus element content is not less than 1.5% by weight. The composition can provide a molded body or composite body which excels in a moisture resistance, a flame retardancy, a smoothness of the surface, and an electric insulation property and a cracking resistance, and hardly generates a harmful substance in burning. A multilayered circuit board is obtained by molding the composition into a sheet; laminating the sheet on an inner layer board; curing the laminated sheet to form an electric insulating layer; and forming an electric conducting layer on the electric insulating layer.

### TECHNICAL FIELD

The present invention relates to a curable resin composition, a composite body, a molded body, and a cured product thereof; a laminated body which is obtained by laminating the cured product; and a multilayered circuit board comprising the laminated body. More particularly, the present invention relates to a multilayered circuit board on which a high density wiring pattern can be formed; a curable resin composition, a composite body, a molded body, a cured product thereof, and a laminated body which is obtained by laminating the cured product, which are suitable to obtain an electric insulating layer of the multilayered circuit board; excels in a moisture resistance, a flame retardancy, a smoothness of the surface, an electrical insulation property, and a cracking resistance; and hardly generates a harmful substance in burning.

### BACKGROUND OF THE ART

As an electronic device is miniaturized, multifunctional, and a high-speed communicational, a multilayered circuit board has been usually used. A multilayered circuit board can be typically obtained by laminating an electric insulating layer (II) on an inner layer board composed of an electric insulating layer (I) and an electric conducting layer (I) formed on the surface thereof, and forming an electric conducting layer (II) on this electric insulating layer (II) further. Layer upon layer of an electric insulating layer and an electric conducting layer may be laminated if necessary. When the electric conducting layer of such a multilayered circuit board has a high density wiring pattern, the electric conducting layer and the board might generate heat and ignite. It is required to give the electric insulating layer the flame retardancy to prevent this ignition.

As a method of giving the electric insulating layer the flame retardancy, a method of adding the halogenated flame retarder to the electric insulating layer, a method of using a halogen-containing polymer as a polymer composing the electric insulating layer, and the like have been executed. Since a used multilayered circuit board is usually incinerated, the electric insulating layer containing halogen element has problem on the environment of generating halogenated harmful substances when incinerating.

Many studies of a resin composition using the flame retarder containing no halogen element have been carried out to avoid the environmental problem.

For example, patent document 1 discloses a flame-retardant resin composition which obtained by mixing a phosphorus-containing compound such as ammonium polyphosphate, and 1,3-phenylene-bis(diphenylphosphate), and a nitrogen-containing cyclic compound with a thermoplastic resin such as polyethylenes, polypropylenes, and polystyrenes; and discloses that various parts may be obtained from this resin composition.

Patent document 2 discloses a curable composition comprising an insulating resin such as alicyclic olefin polymers, aromatic polyethers, and epoxy resins, and particle composed of salt of basic nitrogen-containing compound and phosphoric acid, and discloses that a multilayered circuit board may be provided from this curable composition.

Patent document 3 discloses a flame-retardant resin composition comprising a base resin such as polyester resins, styrene resins, polyamide resins, polycarbonate resins, polyphenylene oxide resins, vinyl resins, olefin resins and acrylic resins, at least one flame retarder selected from the group consisting of (A1) a double salt of amino group-containing nitrogen compound with polyphosphoric acid, (A2) a salt of amino group-containing nitrogen compound with polymetaphosphoric acid, (A3) a polyphosphoric amide, (A4) a salt of amino group-containing nitrogen compound with sulfuric acid, pyrosulfuric acid, an organic sulfonic acid, an organic phosphonic acid or an organic phosphinic acid, and (A5) a cyclic urea compound, and at least one flame-retardant auxiliary selected from the group consisting of (B1) a phosphorus-containing compound, (B2) an aromatic resin, and (B3) an inorganic acid metal salt.

However, the electric insulating layer formed with these conventional resin compositions have a difficulty to form a minute wiring pattern since smoothness on the surface is insufficient, or is insufficient in moisture resistance and flame retardancy even if a smooth surface thereof is excellent.

[Patent Document 1] JP-A-2000-154322

[Patent Document 2] JP-A-2002-121394

[Patent Document 3] JP-A-2003-226818

### DISCLOSURE OF THE INVENTION

### Problems to be Solved by the Invention

An object of the present invention is to provide a multilayered circuit board on which a high density wiring pattern can be formed; and a curable resin composition, a composite body, a molded body, a cured product thereof, and a laminated body which is obtained by laminating the cured product, which are suitable to obtain the multilayered circuit board, excels in moisture resistance, flame retardancy, smoothness of the surface, electrical insulation properties and cracking resistance, and hardly generates harmful substance in burning.

### Means for Solving the Problems

As a result of studies by the present inventor to achieve the objects, it was found that a curable resin composition, which is obtained by mixing an alicyclic olefin polymer, a curing agent, salt of a basic nitrogen-containing compound with a phosphoric acid, and a condensed phosphate ester at a specific proportion and adjusting content of elemental phosphorus within a specific range, not only has high flame retardancy but also improves moisture resistance and the like drastically. The present invention has been completed based on the findings and further studies.

That is, the present invention includes the following modes.

(1) A curable resin composition comprising:

100 parts by weight of an alicyclic olefin polymer (A);

from 1 to 100 parts by weight of a curing agent (B);

from 10 to 50 parts by weight of a salt (C) of a basic nitrogen-containing compound with phosphoric acid; and

from 0.1 to 40 parts by weight of a condensed phosphate ester (D);

of which phosphorus element content is not less than 1.5% by weight based on dry solid.

(2) The curable resin composition according to the above, in which the salt (C) of a basic nitrogen-containing compound with phosphoric acid is at least one compound selected from the group consisting of double salt of melamine-melam-melem polyphosphate, melamine polyphosphate, melam polyphosphate, melem polyphosphate, double salt of melamine-melam-melem orthophosphate, melamine orthophosphate, melam orthophosphate, melem orthophosphate, double salt of melamine-melam-melem pyrophosphate, melamine pyrophosphate, melam pyrophosphate, melem pyrophosphate, double salt of melamine-melam-melem methaphosphate, melamine metaphosphate, melam metaphosphate, and melem metaphosphate.

(3) The curable resin composition according to the above, in which the alicyclic olefin polymer (A) has carboxyl group and/or carboxylic acid anhydride group.

(4) The curable resin composition according to the above, in which the alicyclic olefin polymer (A) has a volume resistivity by ASTM D257 of 1×10¹² Ω·cm or more.

(5) The curable resin composition according to the above, in which the alicyclic olefin polymer (A) has a weight-average molecular weight (Mw) of 10,000 to 250,000.

(6) The curable resin composition according to the above, in which the curing agent (B) is a multivalent epoxy compound.

(7) The curable resin composition according to the above, further comprising a curing accelerator.

(8) The curable resin composition according to the above, in which the curing accelerator is a tertiary amine compound.

(9) The curable resin composition according to the above, further comprising a carboxylic acid anhydride having not less than two acid anhydride groups in a molecule.

(10) A composite body comprising the curable resin composition according to the above, and a fibrous substrate.

(11) The composite body according to the above, in which the fibrous substrate is composed of continuous fiber of a liquid crystalline polymer.

(12) The composite body according to the above, in which the liquid crystalline polymer is a wholly aromatic polyester.

(13) The composite body according to the above, in which the fibrous substrate is from 3 to 55 g/m² in weight per unit area.

(14) The composite body according to the above, of which shape is a film or sheet.

(15) A method for producing a composite body comprising a curable resin composition and a fibrous substrate, comprising:

a step of impregnating the curable resin composition according to the above into the fibrous substrate and

a step of drying the impregnated curable resin composition.

(16) A molded body composed of a film or sheet made of the curable resin composition according to the above.

(17) A molded body comprising a support medium and a coating of the curable resin composition according to the above applied on the support medium.

(18) A cured product obtained by curing the above-mentioned molded body.

(19) A cured product obtained by curing the above-mentioned composite body.

(20) A laminated body comprising:

a board having an electric conducting layer on the surface thereof, and

the above-mentioned cured product laminated on the board, as an electric insulating layer.

(21) A method for producing a laminated body comprising steps of:

thermo-compression bonding the above-mentioned composite body onto a board having an electric conducting layer on the surface thereof, and

curing the bonded composite body to make an electric insulating layer.

(22) A method for producing a laminated body comprising steps of:

thermo-compression bonding the above-mentioned molded body onto a board having an electric conducting layer on the surface thereof, and

curing the bonded molded body to make an electric insulating layer.

(23) A multilayered circuit board comprising:

the above-mentioned laminated body, and

another electric conducting layer formed on the electric insulating layer of the laminated body.

(24) An electronic equipment comprising the above-mentioned multilayered circuit board.

### ADVANTAGES OF THE INVENTION

A composite body, a molded body, a cured product thereof, and a laminated body which is obtained by laminating the cured product, which are formed from a curable resin composition in the present invention, are suitable for a multilayered circuit board on which a high density wiring pattern can be formed, since they excel in a moisture resistance, a flame retardancy, a smoothness of a surface, and an electrical insulation property and a cracking resistance, and hardly generate a harmful substance in burning.

The multilayered circuit board in the present invention has high reliability, because the board is a low thermal expansion coefficient and a high elastic modulus, and has high adhesion with an electric conducting layer even if the electric conducting layer is built on a smooth electric insulating layer by a plating method. Since the multilayered circuit board in the present invention has an excellent electrical property, it can be suitably used as aboard for surface-mounted component, which includes a semiconductor element such as CPU and memory in an electronics device such as computer and cellular phones, and the like.

### BEST MODE FOR CARRYING OUT THE INVENTION

### 1) Curable Resin Composition

A curable resin composition in the present invention comprises an alicyclic olefin polymer (A), a curing agent (B), a salt (C) of a basic nitrogen-containing compound with phosphoric acid, and a condensed phosphate ester (D).

An alicyclic olefin polymer (A) used in the present invention is a general term for a homopolymer, copolymer, and of an alicyclic compound which has polymerizable carbon-carbon unsaturated bond (hereinafter may be referred to as an alicyclic olefin monomer); and derivatives thereof such as hydrogenation products and the like. Moreover, a polymerization manner may be either addition polymerization or ring-opening polymerization.

Examples of an alicyclic olefin polymer includes a ring-opening polymer of norbornene monomer, and a hydrogenation product thereof; an addition polymer of norbornene monomer, and a hydrogenation product thereof; an addition polymer of norbornene monomer and vinyl compound, and a hydrogenation product thereof; an addition polymer of mono-cyclic olefin monomer; a polymer of alicyclic conjugated diene; a polymer of vinyl alicyclic hydrocarbon, and a hydrogenation product thereof; and the like. Moreover, they include a polymer having an equivalent structure to that of an alicyclic olefin polymer derived by a hydrogenation of a polymer, such as a hydrogenation product prepared by hydrogenating an aromatic ring in a vinyl aromatic polymer. Of these, a ring-opening polymer of norbornene monomer, and a hydrogenation product thereof; an addition polymer of norbornene monomer, and a hydrogenation product thereof; an addition polymer of norbornene monomer and vinyl compound, and a hydrogenation product thereof; and a aromatic ring-hydrogenation product of a vinyl aromatic polymer are preferable, and a hydrogenation product of a ring-opening polymer of norbornene monomer is especially preferable. The norbornene monomer is a general term for a monomer which has at least one norbornene ring.

As for suitable alicyclic olefin polymer (A) used in the present invention, a polymer having a carboxyl group and/or a carboxylic acid anhydride group is preferable. The carboxyl group and/or the carboxylic acid anhydride group may bond directly to a carbon atom which composes an alicyclic structure, and may bond through a bivalent group such as methylene group, oxy group, oxycarbonyloxyalkylene group and phenylene group.

A content of the carboxyl group and the carboxylic acid anhydride group is preferably from 5 to 60% by mole, and more preferably from 10 to 50% by mole, especially preferably from 15 to 40% by mole. If the content of the carboxyl group and the carboxylic acid anhydride group in the alicyclic olefin polymer (A) is too small, the plating adhesion and the heat resistance will tend to be reduced, if the content is too large, the electrical insulation properties will tend to be reduced.

Here, the content of the carboxyl group and the carboxylic acid anhydride group means the mole ratio of the number of the carboxyl group and the carboxylic acid anhydride group to the number of total monomer unit in the polymer. The content of the carboxyl group and the carboxylic acid anhydride group can be determined by ¹H-NMR spectrum measurement of the polymer (A).

A method of making content of the carboxyl group and the carboxylic acid anhydride group in the alicyclic olefin polymer (A) within the above-mentioned range is not especially limited. Examples of the method include:

(i) a method of copolymerizing an alicyclic olefin monomer having carboxyl group and/or carboxylic acid anhydride group with a monomer copolymerizable therewith having neither carboxyl group nor carboxylic acid anhydride group such as ethylene, 1-hexene, and 1,4-hexadiene;

(ii) a method of introducing carboxyl group and/or carboxylic acid anhydride group into an alicyclic olefin polymer having neither carboxyl group nor carboxylic acid anhydride group, for example, by grafting an unsaturated carbon-carbon bond-containing compound having carboxyl group and/or carboxylic acid anhydride group to the polymer in the presence of radical initiator;

(iii) a method of converting precursor group into carboxyl group by hydrolysis or the like after polymerizing a norbornene monomer having the precursor group for carboxyl group such as carboxylic acid ester group; and the like.

The alicyclic olefin monomer having carboxyl group includes 8-hydroxycarbonyl-tetracyclo[4.4.0.1^{2,5}.1^{7,10}]dodeca-3-ene, 5-hydroxycarbonyl-bicyclo[2.2.1]hept-2-ene, 5-methyl-5-hydroxycarbonyl-bicyclo[2.2.1]hept-2-ene, 5-carboxymethyl-5-hydroxycarbonyl-bicyclo[2.2.1]hept-2-ene, 8-methyl-8-hydroxycarbonyl-tetracyclo[4.4.0.1^{2,5}.1^{7,10}]dodeca-3-ene, 8-carboxy methyl-8-hydroxycarbonyl-tetracyclo[4.4.0.1^{2,5}.1^{7,10}]dodeca-3-ene, 5-exo-6-endo-dihydroxycarbonyl-bicyclo[2.2.1]hept-2-ene, 8-exo-9-endo-dihydroxycarbonyl-tetracyclo[4.4.0.1^{2,5}.1^{7,10}]dodeca-3-ene, and the like.

Moreover, the alicyclic olefin monomer having carboxylic acid anhydride group includes bicyclo[2.2.1]hept-2-ene-5,6-dicarboxylic anhydride, tetracyclo[4.4.0.1^{2,5}.1^{7,10}]dodeca-3-ene-8,9-dicarboxylic anhydride, hexacyclo[6.6.1.1^{3,6}.1^{10,13}.0^{2,7}.0^{9,14}]heptadeca-4-ene-11,12-dicarboxylic anhydride, and the like.

On the other hand, monomer having neither carboxyl group nor carboxylic acid anhydride group includes bicyclo[2.2.1]hept-2-ene (trivial name: “norbornene”), 5-ethyl-bicyclo[2.2.1]hept-2-ene, 5-butyl-bicyclo[2.2.1]hept-2-ene, 5-ethylidene-bicyclo[2.2.1]hept-2-ene, 5-methylidene-bicyclo[2.2.1]hept-2-ene, 5-vinyl-bicyclo[2.2.1]hept-2-ene, tricyclo[4.3.0.1^{2,5}]deca-3,7-diene (trivial name: “dicyclopentadiene”), tetracyclo[8.4.0.1^{11,14}.0^{2,8}]tetradeca-3,5,7,12,11-tetraene, tetracyclo[4.4.0.1^{2,5}.1^{7,10}]dodeca-3-ene (trivial name: “tetracyclododecene”), 8-methyl-tetracyclo[4.4.0.1^{2,5}.1^{7,10}]dodeca-3-ene, 8-ethyl-tetracyclo[4.4.0. 1^{2,5}.1^{7,10}]dodeca-3-ene, 8-methylidene-tetracyclo[4.4.0. 1^{2,5}.1^{7,10}]dodeca-3-ene, 8-ethylidene-tetracyclo[4.4.0. 1^{2,5}.1^{7,10}]dodeca-3-ene, 8-vinyl-tetracyclo[4.4.0. 1^{2,5}.1^{7,10}]dodeca-3-ene, 8-propenyl-tetracyclo[4.4.0.1^{2,5}. 1^{7,10}]dodeca-3-ene, pentacyclo[6.5.1.1^{3,6.}0^{2,7}.0^{9,13}]pentadeca-3,10-diene, pentacyclo[7.4.0.1^{3,6}.1^{10,13}.0^{2,7}]pentadeca-4,11-diene, cyclopentene, cyclopentadiene, 1,4-methano-1,4,4a,5,10,10a-hexahydroanthracene, 8-phenyl-tetracyclo[4.4.0.1^{2,5}.1^{7,10}]dodeca-3-ene, and the like.

The unsaturated carbon-carbon bond-containing compound having carboxyl group and/or carboxylic acid anhydride group used for the method of (ii) includes an unsaturated carboxylic acid compound such as acrylic acid, methacrylic acid, α-ethyl acrylic acid, 2-hydroxyethyl acrylic acid, 2-hydroxyethyl methacrylic acid, maleic acid, fumaric acid, itaconic acid, endo-cis-bicyclo[2.2.1]hept-5-ene-2,3-dicarboxylic acid, and methyl-endo-cis-bicyclo[2.2.1]hept-5-ene-2,3-dicarboxylic acid; an unsaturated carboxylic acid anhydride such as maleic anhydride, chloro maleic anhydride, butenyl succinic anhydride, tetrahydro phthalic anhydride, and citraconic anhydride; and the like.

The norbornene monomer having a precursor group for carboxyl group used for the method of (iii) includes 8-methyl-8-methoxycarbonyl-tetracyclo[4.4. 0.1^{2,5}.1^{7,10}]-dodeca-3-ene, 5-methoxycarbonyl-bicyclo[2.2.1]hept-2-ene, 5-methyl-5-methoxycarbonyl-bicyclo[2.2.1]hept-2-ene, and the like.

An alicyclic olefin polymer (A) may have a functional group (hereinafter may be referred to as “other functional group”) other than a carboxyl group and a carboxylic acid anhydride group. The other functional group may include alkoxycarbonyl group, cyano group, hydroxyl group, epoxy group, alkoxy group, amino group, amido group, imido group, and the like. The amount of the other functional group is preferably 30 mol % or less, more preferably 10 mol % or less, and particularly preferably 1 mol % or less compared with a carboxyl group and a carboxylic anhydride group.

The glass transition temperature (Tg) of the alicyclic olefin polymer (A) used in the present invention, but not particularly limited, ranges preferably from 120 to 300° C. If the Tg is too low, the keeping of enough electrical insulation properties of the electric insulating layer under the high temperature will tend to be difficult, and if the Tg is too high, the electric conducting layer will tend to be damaged easily since a crack occurs when the multilayered wiring plate receives a high impact.

An alicyclic olefin polymer (A) used in the present invention preferably has electrical insulation properties. Volume resistivity of alicyclic olefin polymer (A) by ASTM D257 is preferably 1×10¹² Ω·cm or more, more preferably 1×10¹³ Ω·cm or more, and particularly preferably 1×10¹⁴ Ω·cm or more.

An alicyclic olefin polymer (A) used in the present invention has a weight average molecular weight (Mw) of usually 10,000 to 250,000, preferably 15,000 to 150,000, and more preferably 20,000 to 100,000. If Mw of alicyclic olefin polymer (A) is too small, a strength of the obtained electric insulating layer will tend to be insufficient, and electrical insulation properties will tend to be reduced. On the other hand, when Mw is too large, an accuracy of the wiring pattern will tend to be reduced since the compatibility of alicyclic olefin polymer (A) and curing agent (B) will tend to be reduced, then the surface roughness of the electric insulating layer will be large. The Mw of the alicyclic olefin polymer (A) may be determined as a polystyrene equivalence by a gel permeation chromatography (GPC).

Adjusting of Mw in alicyclic olefin polymer (A) within the above-mentioned range may be carried out by the usual method. A method of adding a molecular weight modifier such as a vinyl compound and a diene compound within the range of about from 0.1 to 10 mol % based on the total amount of a monomer in a ring-opening polymerization of an alicyclic olefin by using a titanium-based or tungsten-based catalyst is mentioned as an example of the method.

The molecular weight modifier includes α-olefin compounds such as 1-butene, 1-pentene, 1-hexene and 1-octene; styrene compounds such as styrene and vinyltoluene; ether compounds such as ethyl vinyl ether, i-butyl vinyl ether and allyl glycidyl ether; halogen-containing vinyl compounds such as allyl chloride; other vinyl compounds such as allyl acetate, allyl alcohol, glycidyl methacrylate, and acrylamide; non-conjugated diene compounds such as 1,4-pentadiene, 1,5-hexadiene, 1,6-heptadiene, 2-methyl-1,4-pentadiene and 2,5-dimethyl-1,5-hexadiene; conjugated diene compounds such as 1,3-butadiene, 2-methyl-1,3-butadiene, 2,3-dimethyl-1,3-butadiene, 1,3-pentadiene and 1,3-hexadiene; and the like.

A curing agent (B) used in the present invention is not limited if an alicyclic olefin polymer (A) can be cross-linked by heating. In particular, a compound which can form the cross-linked structure by reacting with a carboxyl group and/or a carboxylic acid anhydride group in the alicyclic olefin polymer (A) is preferable.

The curing agent includes multivalent epoxy compounds, multivalent isocyanate compounds, multivalent amine compounds, multivalent hydrazide compounds, aziridine compounds, basic metal oxides, organometallic halides, and the like. These curing agents can be used singly or in combination of two or more. Moreover, peroxide can be used as a curing agent.

The multivalent epoxy compound is a compound which has not less than two epoxy groups in a molecule. Examples of the multivalent epoxy compound include glycidyl ether-type epoxy compounds such as phenol novolac-type epoxy compounds, cresol novolac-type epoxy compounds, cresol-type epoxy compounds, bisphenol A-type epoxy compounds, bisphenol F-type epoxy compounds and hydrogenated bisphenol A-type epoxy compounds; multivalent epoxy compounds such as cycloaliphatic epoxy compounds, glycidyl ester-type epoxy compounds, glycidyl amine-type epoxy compounds and isocyanurate-type epoxy compounds, and the like.

As the multivalent isocyanate compounds, diisocyanates having 6 to 24 of carbon atoms or triisocyanates having 6 to 24 of carbon atoms are preferable. Examples of diisocyanate include 2,4-tolylene-diisocyanate, 2,6-tolylene-diisocyanate, 4,4′-diphenylmethane-diisocyanate, hexamethylene diisocyanate, p-phenylene diisocyanate, and the like. Examples of triisocyanate include 1,3,6-hexamethylene triisocyanate, 1,6,11-undecane triisocyanate, bicycloheptane triisocyanate, and the like.

The multivalent amine compound is a compound which has not less than two amino groups in a molecule. Examples of the multivalent amine compound include aliphatic multivalent amine compounds having 4 to 30 of carbon atoms, aromatic multivalent amine compounds, and the like. In here, the multivalent amine compound does not include compounds having unconjugated nitrogen-carbon double bond such as guanidine compound.

The aliphatic multivalent amine compound includes hexamethylenediamine, N,N′-dicinnamylidene-1,6-hexanediamine, and the like.

The aromatic multivalent amine compounds includes 4,4′-methylenedianiline, m-phenylenediamine, 4,4′-diaminodiphenyl ether, 4′-(m-phenylenediisopropylidene)dianiline, 4,4′-(p-phenylenediisopropylidene)dianiline, 2,2′-bis[4-(4-aminophenoxy)phenyl]propane, 1,3,5-benzentriamine, and the like.

The multivalent hydrazide compound includes iso-phthalic acid dihydrazide, terephthalic acid dihydrazide, 2,6-naphthalene dicarboxylic acid dihydrazide, maleic acid dihydrazide, itaconic acid dihydrazide, trimellitic acid dihydrazide, 1,3,5-benzene tricarboxylic acid dihydrazide, pyromellitic acid dihydrazide, and the like.

The aziridine compound includes tris-2,4,6-(1-aziridinyl)-1,3,5-triazine, tris-[1-(2-methyl)aziridinyl]-phosphine oxide, hexa[1-(2-methyl) aziridinyl]triphosphatriazine, and the like.

The peroxide includes organic peroxides such as ketone paroxide, peroxyketal, hydroperoxide, diallyl peroxide, diacyl peroxide, peroxyester and peroxydicarbonate, and the like.

In these curing agents, multivalent epoxy compound is preferable and bisphenol A-type epoxy compound such as bisphenol A bis(propylene glycol glycidyl ether) ether is more preferable, since a reactivity with alicyclic olefin polymer (A) is gradual, and a melting, a fabricating and a laminating of an obtained composite body are easy.

The amount used of a curing agent (B) ranges from 1 to 100 parts by weight, preferably from 5 to 80 parts by weight, and more preferably from 10 to 50 parts by weight based on 100 parts by weight of alicyclic olefin polymer (A).

The curable resin composition in the present invention can preferably comprise a curing accelerator further from the viewpoint that a cured product with a high heat resistance can be easily obtained. For example, when a multivalent epoxy compound is used as curing agent (B), curing accelerator such as tertiary amine compounds, and trifluorinated boron complex compounds is suitably used. Among them, tertiary amine compounds are preferably used since a use of tertiary amine compound improves lamination properties to microscopic wiring, insulating resistance, heat resistance and chemical resistance.

The tertiary amine compound includes acyclic tertiary amine compounds such as benzyldimethylamine, triethanolamine, triethylamine, tributylamine, tribenzylamine and dimethylformamide; nitrogen-containing heterocyclic compounds such as pyrazoles, pyridines, pyrazines, pyrimidines, indazoles, quinolines, isoquinolines, imidazoles and triazoles, and the like. Among them, imidazoles are preferred, and substituted imidazole compounds are most preferred.

The substituted imidazole compound includes alkyl substituted imidazole compounds such as 2-ethylimidazole, 2-ethyl-4-methylimidazole, bis-2-ethyl-4-methylimidazole, 1-methyl-2-ethylimidazole, 2-isopropylimidazole, 2,4-dimethylimidazole, and 2-heptadecylimidazole; imidazole compounds substituted with a hydrocarbon group having a ring structure such as aryl group or aralkyl group such as 2-phenylimidazole, 1-benzyl-2-methylimidazole, 1-benzyl-2-ethylimidazole, benzimidazole, 2-ethyl-4-methyl-1-(2′-cyanoethyl) imidazole, 2-ethyl-4-methyl-1-[2′-(3″,5″-diamino triazinyl)ethyl]imidazole, and 1-benzyl-2-phenyl imidazole; and the like. These curing accelerators are used as single or in combination of two or more. Among them, imidazole compounds substituted with a hydrocarbon group having a ring structure are preferred, and 1-benzyl-2-phenylimidazole is most preferred.

The amount compounded of a curing accelerator is appropriately selected depending on intended use, and usually from 0.001 to 30 parts by weight, preferably from 0.01 to 10 parts by weight, and more preferably from 0.03 to 5 parts by weight based on 100 parts by weight of alicyclic olefin polymer (A).

A salt (C) of a basic nitrogen-containing compound with a phosphoric acid used in the present invention is a compound which is halogen-free and shows flame retardancy. Examples of phosphoric acid composing the salt include inorganic phosphoric acid such as orthophosphoric acid, phosphorous acid, hypophosphorous acid, metaphosphoric acid, pyrophosphoric acid, triphosphoric acid, and tetraphosphoric acid; organophosphoric acid such as phosphonic acid, and phosphinico-carboxylic acid; and the like. Orthophosphoric acid is preferable among these. A condensed phosphoric acid (polyphosphoric acid) is preferable as for the phosphoric acid. As the polyphosphoric acid, acyclic polyphosphoric acid, cyclic polymetaphosphoric acid, and the like are mentioned. The present invention is not especially restricted by a degree of condensation, though the condensation degree of the polyphosphoric acid is usually from 3 to 50. A condensate of the orthophosphoric acid is used especially preferably in the present invention.

On the other hand, examples of the basic nitrogen-containing compound composing the salt include melamine, melamine derivative, a compound having a similar structure to the melamine, condensate of melamine, and the like. More specific examples of the basic nitrogen-containing compound include a compound with a triazine structure such as melamine, ammelide, ammeline, formoguanamine, guanylmelamine, melaminecyanulate, benzoguanamine, acetoguanamine, succinoguanamine, melam, melem, metone, and melone; sulfates of them; and melamine resins; and the like. Melamine, melam, melem, and a double salt thereof are especially preferable among these.

Concrete examples of a salt (C) of a basic nitrogen-containing compound with a phosphoric acid include ammonium phosphate, ammonium polyphosphate, melamine phosphate, melamine pyrophosphate, melamine polyphosphate, melam polyphosphate, melem polyphosphate, ammonium polyphosphate, phosphate ester amide, melamine-melam-melem double salt of polyphosphoric acid; melamine pentaerythritol bis phosphate, dimelamine pentaerythritol bis phosphate, dimelamine 1-hydroxy ethylidene-1,1-diphosphonate, tetramelamine 1-hydroxy ethylidene-1,1-diphosphonate, nitrilotri(methylene phosphonic acid) tetramelamine salt, nitrilotri(methylene phosphonic acid) hexamelamine salt, melamine phenylphosphonate, dimelamine phenylphosphonate, melamine 3-(phenyl phosphinico)propionate, dimelamine 3-(phenyl phosphinico)propionate; melam salts or melem salts corresponding to the above-mentioned melamine salt, and double salts thereof, and the like.

Examples of a commercially available salt (C) of a basic nitrogen-containing compound with a phosphoric acid include “MPP-A” which is obtained by crushing a salt of polyphosphoric acid and melamine (manufactured by SANWA CHEMICAL CO., LTD.), “PMP” (manufactured by NISSAN CHEMICAL INDUSTRIES, LTD.), “ADK STAB FP-2200” (manufactured by ADEKA CORPORATION), “Taien S” which is obtained by treating ammonium polyphosphate with melamine resin or the like to become low-water solubility (manufactured by Taihei Chemical Industrial Co., Ltd.), “Sumisafe P” and “Sumisafe PM” (manufactured by Sumitomo Chemical Co., Ltd.), “Exolit 462” (manufactured by HOECHST AG), “AMGARD MC” (manufactured by Albright & Wilson Corp.), and the like. Furthermore, “Exolit VP IFR-23” which have been improved in flame-retardant effect by using other auxiliary components in combination with ammonium polyphosphate (manufactured by Hoechst AG), “SPINFLAM MF80/PP”, “SPINFLAM MF82/PP”, and “SPINFLAM MF82/PS” (manufactured by Montecatini Edison S.P.A), and the like are mentioned.

Among these, melamine-melam-melem double salt of polyphosphoric acid, melamine polyphosphate, melam polyphosphate, melem polyphosphate, melamine-melam-melem double salt of orthophosphoric acid, melamine orthophosphate, melam orthophosphate, melem orthophosphate, melamine-melam-melem double salt of pyrophosphoric acid, melamine pyrophosphate, melam pyrophosphate, melem pyrophosphate, melamine-melam-melem double salt of meta phosphoric acid, melamine metaphosphate, melam metaphosphate, and melem metaphosphate are preferable.

A salt (C) of a basic nitrogen-containing compound with a phosphoric acid may be a salt formed by a substantial equimolar reaction of the basic nitrogen-containing compound such as melamine, and phosphoric acid such as orthophosphoric acid and polyphosphoric acid. In addition, a part of the acid functional groups of salt (C) may be in a free state.

A salt (C) of a basic nitrogen-containing compound with phosphoric acid can be obtained, for example, by reacting melamine and phosphoric acid in water slurry, and filtering, washing and drying the reactive product.

The salt (C) of a basic nitrogen-containing compound with a phosphoric acid obtained by the method has particulate shape. A particle diameter of a salt (C) of a basic nitrogen-containing compound with phosphoric acid is preferably 100 μm or less, and more preferably 50 μm or less. It is preferable to use a salt (C) having a particle diameter of 0.5 to 20 μm in view of not only an onset of high flame retardancy but also a remarkably high strength of a molded article.

The amount of a salt (C) of a basic nitrogen-containing compound with a phosphoric acid is usually from 10 to 50 parts by weight, preferably from 15 to 40 parts by weight, and more preferably from 20 to 30 parts by weight based on 100 parts by weight of alicyclic olefin polymer (A).

A condensed phosphate ester (D) used in the present invention includes compounds represented by the formula (I).

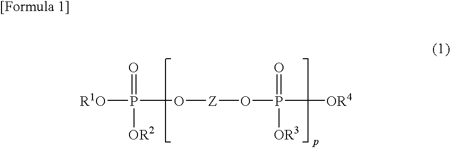

In the formula (I), R¹, R², R³, and R⁴ are aryl group which may have a substituent; Z is a bivalent aromatic group; p is an integer of one or more.

In the formula (I), p is preferably an integer from 1 to 30. Moreover, as the aryl group represented by R¹, R², R³, and R⁴, an aryl group of C₆₋₂₀ such as phenyl group and naphthyl group is mentioned. Mentioned as a substituent in the aryl group is alkyl group such as methyl group and ethyl group. The bivalent aromatic group includes arylene group as phenylene group, and naphthylene group; biphenylene group; bisphenol residue such as bisphenol A residue, bisphenol D residue, bisphenol AD residue, and bisphenol S residue); and the like.

The condensed phosphate ester (D) includes resorcinol phosphates such as resorcinol bis(diphenyl phosphate), resorcinol bis(dicresylphosphate), and resorcinol bis(dixylenyl phosphate); hydroquinone phosphates such as hydroquinone bis(diphenyl phosphate), hydroquinone bis(dicresyl phosphate), and hydroquinone bis(dixylenyl phosphate); biphenol phosphates such as biphenol bis(diphenyl phosphate), biphenol bis(dicresyl phosphate), and biphenol bis(dixylenyl phosphate); bisphenol phosphates such as bisphenol A bis(diphenyl phosphate), bisphenol A bis(dicresyl phosphate), and bisphenol A bis(dixylenyl phosphate); bisphenol S bis(diphenyl phosphate); resorcinol bis(dixylyl phosphate); hydroquinone bis(dixylyl phosphate); bisphenol A bis(dixylenyl phosphate); resorcinol bis(ditolyl phosphate); bisphenol A bis(ditolyl phosphate); and the like. The resorcinol phosphates are preferable among these.

The amount of a condensed phosphate ester (D) ranges usually from 0.1 to 40 parts by weight, preferably from 1 to 30 parts by weight, and more preferably from 5 to 20 parts by weight, per 100 parts by weight of alicyclic olefin polymer (A).

In addition, a curable resin composition in the present invention may comprise a halogen-free flame retarder. The halogen-free flame retarders include inorganic flame retarders such as aluminum hydroxide, magnesium hydroxide, zinc borate, guanidine sulfamate, zirconium compounds, molybdenum compounds, aluminum borate, and tin compounds; organometallic compounds such as ferrocene; phosphorus flame retarders other than salts (C) of basic nitrogen-containing compound with phosphoric acid and condensed phosphate ester (D) such as phosphazene compound, phosphorus-containing epoxy compound; and the like.

A curable resin composition in the present invention may be comprise a filler so as to give desired performance. Examples of fillers include carbon black, silica gel, alumina, barium titanate, talc, mica, glass beads, glass hollow sphere, and the like.

In the present invention, carboxylic acid anhydride which has two or more of acid anhydride groups in a molecule may be added to improve an adhesion force with an electric conducting layer. The carboxylic acid anhydrides which have two or more of acid anhydride groups in a molecule are not limited as long as they dissolve to organic solvent composing the curable resin composition. Examples of carboxylic acid anhydride include anhydrous pyromellitic acid, hexahydro pyromellitic acid anhydride, cyclobutane tetracarboxylic dianhydride, naphthalene tetracarboxylic dianhydride, benzophenone tetracarboxylic dianhydride, undecahydro benzophenone tetracarboxylic dianhydride, 1,2,3,4-tetrahydro naphthalene-2,3-dicarboxylic anhydride, ethylene glycol bis(anhydro-trimellitate), ethylene glycol bis(anhydro-trimellitate) monoacetate, glycerin bis(anhydro-trimellitate) monoacetate, 4-(2,5-dioxo-tetrahydrofuran-3-yl)-1,2,3,4-tetrahydronaphtalene-1,2-dicarboxylic anhydride, 5-(2,5-dioxo-tetrahydroxy-furyll)-3-methyl-3-cyclohexene-1,2-dicarboxylic anhydride, 1,2,3,4-butane tetracarboxylic dianhydride, 4,4′-sulfonyl diphthalic anhydride, and the like. Among them, from the viewpoint of the compatibility with other ingredients in the curable resin composition, ethylene glycol bis(anhydro-trimellitate), ethylene glycol bis(anhydro-trimellitate) monoacetate or glycerin bis(anhydro-trimellitate) monoacetate is preferable, and ethylene glycol bis(anhydro-trimellitate) monoacetate or glycerin bis(anhydro-trimellitate) monoacetate is especially preferable.

Other additives may be comprised in the curable resin composition of the present invention. Examples of the additives include laser processability improvers, soluble polymers in the solution of oxidizing compounds, heat stabilizers, weathering stabilizers, antioxidants, leveling agents, antistatic agents, slip agents, antiblocking agents, antifog agents, lubricant, dye, pigments, natural oil, synthetic oil, wax, emulsion, magnetic substance, dielectric characteristic adjusters, toughness agents, fillers, solvents, and the like.

The curable resin composition in the present invention may be adjusted to a moderate viscosity for impregnating to a fibrous substrate, for spreading, sparging or casting to a support medium, and for molding. A solvent is usually used for the viscosity adjustment.

The solvent used in the present invention has a boiling point of preferably from 30 to 250° C., and more preferably from 50 to 200° C. If the boiling point of the solvent is in this range, it is preferable to remove the solvent by heating to evaporate, after an impregnation, a spreading, a molding and the like. Examples of solvent include aromatic hydrocarbons such as toluene, xylene, ethylbenzene and trimethylbenzene; aliphatic hydrocarbons such as n-pentane, n-hexane and n-heptane; alicyclic hydrocarbons such as cyclopentane, and cyclohexane; alcohols such as methanol, 1-propanol, 1-butanol, 2-butanol, and iso-propyl alcohol; ketones such as methyl ethyl ketone, methyl isobutyl ketone, cyclopentanone, and cyclohexanone; and the like.

If a viscosity of the obtained curable resin composition is suitable for the impregnation, spreading and the like, the amount used of the solvent is not particularly limited. An organic solvent may be used in the solid density of the curable resin composition ranging usually from 5 to 70% by weight, preferably from 10 to 65% by weight, and more preferably from 20 to 60% by weight.

A curable resin composition in the present invention has a phosphorus element content, which is based on dry solid, of not less than 1.5% by weight, preferably from 1.5 to 3% by weight, and more preferably from 1.5 to 2.5% by weight. It may be undesirable that the phosphorus element content is less than 1.5% by weight, since flame retardancy is inferior. The phosphorus element content is determined by the following steps of; removing a volatile matter from a curable resin composition by drying in a vacuum at 100° C.; weighing the curable resin composition; capturing an elemental phosphorus to an aqueous solution as a phosphoric ion by the oxygen combustion flask method in accordance with JIS K 6233-1:96; and measuring a density thereof by an ion chromatography analysis based on JIS K 0127:01.

A curable resin composition is not particularly limited by a preparation method. For example, the curable resin composition can be obtained by mixing an alicyclic olefin polymer (A), a curing agent (B), a salt (C) of a basic nitrogen-containing compound with phosphoric acid, a condensed phosphate ester (D), and the additive if necessary such as a solvent and a filler in accordance with conventional methods.

Examples of a blending machine used for mixing include a magnetic stirrer, a high-speed homogenizer, a disperser, a planetary mixer, a biaxial mixer, a ball mill, a triple roll mill, and the like.

The temperature for mixing is preferably within the temperature where the curing reaction by the curing agents (B) is not caused, and preferably below the boiling point of the organic solvent to be used.

### 2) Composite Body

A composite body in the present invention comprises the above-mentioned curable resin composition and a fibrous substrate. Examples of the fibrous substrate used in the present invention include a woven cloth such as a roving cloth, chopped mat, and surfacing mat; a nonwoven cloth; bunch or bundle of fibers; and the like. Among these fibrous substrates, woven cloth is preferable from the viewpoint of the dimensional stability, and nonwoven cloth is preferable from the viewpoint of the processability. A woven cloth and a nonwoven cloth may be laminated to aim at having both features of the woven cloth and the nonwoven cloth.

Moreover, the one which is obtained by compressing woven cloth or nonwoven cloth by a heat roll, a press, or the like is suitable.

A woven cloth or nonwoven cloth can be made smooth and thin by a heat compression treatment. As a result, a thickness of the electric insulating layer can be reduced. And it becomes easy to control the thickness when laminating. Furthermore, an impregnation to a woven cloth or a nonwoven cloth of the curable resin composition can be improved.

A fiber composing the fibrous substrate is not especially limited by the shape, but may be a filament which section of is a round, a spread yarn obtained by making fiber bunch ribbon base, a mixed yarn using two or more different materials. Materials of fiber may be organic substances such as liquid crystalline polymer, aramid, polybenzoxasole, and native cellulose, and may be inorganic substances such as glass and carbons. Among them, liquid crystalline polymer is preferable since it excels in the flame retardancy, the heat resistance, the water permeability-proof, the electrical property, and the linear expansion coefficient.

In the present invention, a fiber obtained by spinning the liquid crystalline polymer is suitably used. The liquid crystalline polymer is polyester and/or polyester amid which are obtained by polymerizing or copolymerizing compounds properly selected singly or in properly combination from the group consisting of aromatic or aliphatic dihydroxy compound, (b) aromatic or aliphatic dicarboxylic acid, (c) aromatic hydroxy carboxylic acid, and (d) aromatic diamine, aromatic hydroxylamine or aromatic amino carboxylic acid. A wholly aromatic polyester which doesn't substantially have a unit of aliphatic compound in the main chain is preferable as the liquid crystalline polymer used for the present invention.

The wholly aromatic polyester is obtained by copolymerizing monomers such as aromatic diols, aromatic dicarboxylic acids, and aromatic hydroxy carboxylic acids. Examples of the wholly aromatic polyester include copolymer of p-hydroxybenzoic acid and 2-hydroxy-6-naphthoic acid, copolymer of p-hydroxybenzoic acid and 6-hydroxy-2-naphthoic acid, copolymer of p-hydroxybenzoic acid and 4,4′-dihydroxybiphenyl, copolymer of terephthalic acid and 4,4′-dihydroxybiphenyl, copolymer of p-hydroxybenzoic acid, terephthalic acid, and 4,4′-dihydroxybiphenyl.

A fiber of the liquid crystalline polymer may be mixed with other fibers such as glass, aramid, polybenzoxasole, and native celluloses.

A fibrous substrate composed of a continuous fiber of the liquid crystalline polymer suitably used for the present invention includes a nonwoven cloth comprising a fiber of wholly aromatic polyester highly orientated by the melt blowing method at a fiber spinning. “VECRUS”, “VECTRAN” (both are brand name of the Kuraray Co., Ltd.), or the like can be used specifically as the nonwoven cloth.

A thickness of the obtained electric insulating layer can be arbitrarily changed by adjusting the weight per unit area of the fibrous substrate used for the present invention. The weight per unit area of the fibrous substrate ranges preferably from 3 to 55 g/m², and more preferably from 6 to 45 g/m². If the weight per unit area is too small, the coating will become difficult since strength of the fibrous substrate will become in insufficient. Moreover, if the weight per unit area is too large, a control of the thickness will become difficult at lamination since reducing the thickness of the obtained electric insulating layer will become difficult.

The composite body in the present invention is usually obtained by impregnating the above-mentioned fibrous substrate with the above-mentioned curable resin composition; and drying it. The method of impregnating includes, but not especially limited, for example, a method of soaking a fibrous substrate to a curable resin composition of which viscosity or the like are adjusted by an organic solvent, a method of spreading or sparging a curable resin composition of which viscosity or the like are adjusted by an organic solvent on a fibrous substrate, and the like. In the spreading or sparging method, a curable resin composition may be spread or sparged on a fibrous substrate placed on the following support medium. Drying is preferably carried out at a temperature lower than the curing temperature of the curable resin composition. The drying temperature ranges usually from 20 to 300° C., and preferably from 30 to 200° C. If the drying temperature is too high, an obtained composite body will not be in an uncured or semicured state since a curing reaction will progress too much. Moreover, a drying time ranges usually from 30 seconds to 1 hour, and preferably from 1 minute to 30 minutes.

In a composite body of the present invention, the curable resin composition is preferably in an uncured or semicured state.

In here, “the uncured state” means a state that all alicyclic olefin polymers (A) dissolve substantially when the composite body immersed into a solvent which can dissolve the alicyclic olefin polymer (A).

Moreover, “the semicured state” means a state of the curable resin composition is cured halfway and may be cured further if the curable resin composition is heated, preferably, a state that a part (specifically not less than 7% by weight) of alicyclic olefin polymer (A) dissolves to a solvent which can dissolve the alicyclic olefin polymer (A) or a state that a volume of a composite body (swelling rate) is 200% or more based on a volume of a composite body before immersing in a solvent for 24 hours.

The amount of a fibrous substrate in the composite body of the present invention ranges usually from 20 to 90% by weight, and preferably from 30 to 85% by weight. If the amount of the fibrous substrate is too small, a flame retardancy will be reduced, and if it is too large, a control of a thickness at lamination will be difficult.

Shape of the composite body in the present invention is not particularly limited, and preferably film or sheet. The thickness of the film or sheet is usually from 1 to 150 μm, preferably from 3 to 100 μm, and more preferably from 5 to 80 μm.

### 3) Molded Body

A molded body of the present invention is one obtained by molding the above-mentioned curable resin composition. A shape of the molded body in the present invention, but not especially limited, is preferably, film or sheet. A thickness of the film or sheet ranges usually from 0.1 to 150 μm, preferably from 0.5 to 100 μm, and more preferably from 1 to 80 μm.

The molded body in the present invention may be usually obtained by the successive steps of: spreading, sparging, or casting the above-mentioned curable resin composition on a support medium; and then drying it.

The support medium includes resin films, metal foil, and the like. Examples of the resin films include polyethylene terephthalate films, polypropylene films, polyethylene films, polycarbonate films, polyethylene naphthalate films, polyarylate films, nylon films, and the like.

Among these resin films, polyethylene terephthalate films and polyethylene naphthalate films are preferred in terms of having good heat resistance, chemical resistance and peeling properties. Examples of the metal foil include copper foil, aluminum foil, nickel foil, chromium foil, gold foil and silver foil. Among these metal foils, copper foil, particularly electrolytic copper foil or rolled copper foil, is preferred in terms of good electrical conductivity.

The thickness of the support medium is, but not particularly limited, usually from 1 to 150 μm, preferably from 2 to 100 μm, and more preferably from 5 to 80 μm from a viewpoint of workability or the like.

A surface average roughness Ra of the support medium is usually 300 nm or less, preferably 150 nm or less, and more preferably 100 nm or less.

If the surface average roughness Ra of a support medium is too large, a formation of a minute wiring pattern as a electric conducting layer is difficult since a surface average roughness Ra of the electric insulating layer formed by curing an obtained composite molded body is large.

Methods for coating of the curable resin composition include the methods such as dip coating, roll coating, curtain coating, die coating, slit coating, gravure coating, and the like.

The drying after the coating is preferably carried out at a temperature lower than the curing temperature of the curable resin composition. The drying temperature ranges usually from 20 to 300° C., and preferably from 30 to 200° C.

If the drying temperature is too high, an obtained composite body will not be in an uncured or semicured state since a curing reaction will progress too much. Moreover, a drying time ranges usually from 30 seconds to 1 hour, preferably from 1 minute to 30 minutes.

As well as the above-mentioned composite body, in the molded body of the present invention, the curable resin composition is preferably in an uncured or the semicured state. The obtained molded body formed on a support medium can be used as it is attached on the support medium or after peeling off from the support medium.

### 4) Cured Product

A cured product in the present invention is one obtained by curing the above-mentioned molded body or composite body of the present invention.

The curing is usually carried out by heating the above-mentioned molded body or composite body.

Curing conditions are properly selected according to the type of the curing agent.

The curing temperature ranges usually from 30 to 400° C., preferably from 70 to 300° C., and more preferably from 100 to 200° C. A curing time ranges from 0.1 to 5 hours, and preferably 0.5 to 3 hours. A heating method may be, but not be especially limited, for example, carried out by using the electric oven.

Before the curing, it is preferable to install the steps of: contacting a compound having a metallic coordinating ability with the above-mentioned molded body or composite body; and then washing with good solvent (for example, water) for the compound having a metallic coordinating ability. By this step, the surface of the molded body or composite body becomes smooth, and an adhesion with a thin metallic film covered on them in the post-processing can be improved.

Examples of the compound having a metallic coordinating ability include imidazoles such as 1-(2-aminoethyl)-2-methylimidazole; pyrazoles; triazoles; triazines; and the like.

### 5) Laminated Body

A laminated body in the present invention is one obtained by laminating a board having an electric conducting layer (I) on the surface and an electric insulating layer composed of the cured product in the present invention. The board used for the laminated body of the present invention is an electrically insulating substrate having an electric conducting layer (I) on the surface thereof. The electrically insulating substrate is one formed by curing a curable resin composition which comprises well-known electrically insulating material such as alicyclic olefin polymers, epoxy resins, maleimide resins, (meth) acrylic resins, diallylphthalate resins, triazine resins, polyphenylether, and glass.

The electric conducting layer (I) is, but not limited, usually a layer having a wiring made of conductor such as electrically conductive metals. Moreover, the electric conducting layer (I) may have various circuits further. A framework, thickness and of the wiring and circuit are not limited in the electric conducting layer (I). Examples of the board having an electric conducting layer (I) on the surface include a printed circuit board, a silicon wafer substrate, and the like. A thickness of the board having an electric conducting layer (I) on the surface ranges usually from 10 μm to 10 mm, preferably from 20 μm to 5 mm, and more preferably from 30 μm to 2 mm.

In the board having an electric conducting layer (I) used in the present invention, the surface of the electric conducting layer (I) is preferably pretreated to improve an adhesion with an electric insulating layer.

As a pretreatment method, the well-known technology can be used without especially limiting. Examples of the pretreatment method include: a method of oxidation treatment, in case of the electric conducting layer (I) composed of copper, by contacting a strong alkaline oxidizing solution to the surface of the electric conducting layer (I) for forming a layer of copper oxide to make the surface roughened; a method of reduction with sodium borohydride, formalin or the like after oxidization of the surface of the electric conducting layer (I) by the above-mentioned method; a method of precipitating a plating on the electric conducting layer (I) to make the surface roughened; a method of contacting an organic acid to the electric conducting layer (I) and eluting grain boundary of copper to make the surface roughened; a method of forming a primer layer on the electric conducting layer (I) by thiol compounds, the silicon analogue or the like; and the like. Among them, from the viewpoint of easiness of the shape maintenance of a minute wiring pattern, the method of contacting an organic acid to the electric conducting layer (I) and eluting grain boundary of copper to make the surface roughened, and the method of forming a primer layer on the electric conducting layer (I) by thiol compounds, the silicon analogue or the like are preferable.

A laminated body in the invention can be produced by thermo compression bonding the molded body or composite body in the present invention onto the board having an electric conducting layer (I) on the surface; and curing it to form an electric insulating layer.

The concrete examples of the method of the thermo compression bonding include a method that is the thermo compression bonding (lamination) by overlapping a molded body or composite body with a support medium to contact with an electric conducting layer (I) of the board by using a pressure machine such as a pressure laminator, a press, a vacuum laminator, a vacuum press, a roll laminator, and the like.

By the thermo compression bonding, the electric conducting layer (I) on the surface of the board and the molded body or composite body of the present invention can be united so that gap does not exist substantially in those interfaces. Moreover, in case of using a metallic foil as the support medium, since an adhesion of a molded body and the metallic foil (support medium) improves by this thermo compression bonding, the metallic foil itself can be used as a following electric conducting layer (II) of multilayered circuit board.

The temperature during the thermo compression bonding is usually from 30 to 250° C., and preferably from 70 to 200° C.; the strength of the compression bonding is usually from 10 kPa to 20 MPa, and preferably from 100 kPa to 10 MPa; and the time of the thermo compression bonding is usually from 30 seconds to 5 hours, and preferably from 1 minute to 3 hours. The thermo compression bonding is preferably carried out under reduced pressure to improve embedding properties of wiring and to suppress generation of blisters. A pressure of the atmosphere during the thermo compression bonding is usually from 100 kPa to 1 Pa, and preferably from 40 kPa to 10 Pa.

Then, an electric insulating layer is formed by curing the molded body or composite body which is thermo compression bonded. The curing is usually carried out by heating a molded body or composite body which is thermo compression bonded on the electric conducting layer (I). The curing can be carried out with the above mentioned thermo compression bonding operation at the same time. Moreover, the curing can be carried out after the thermo compression bonding operation in a short time and in condition that curing doesn't happen, that is comparatively low temperature. A curing temperature ranges usually from 30 to 400° C. A curing time ranges usually from 0.1 to 5 hours.

Moreover, two or more of molded bodies or composite bodies may be laminated contiguously on the electric conducting layer of the board for the purpose of improving smoothness of the electric insulating layer or the purpose of increasing thickness of the electric insulating layer.

### 6) Multilayered Circuit Board

A multilayered circuit board in the present invention is one obtained by forming an electric conducting layer (II) on the electric insulating layer of the laminated body in the present invention.

In case of using a molded body which is laminated on a support medium composed of a resin film at manufacturing the laminated body, the molded body (electric insulating layer) which is laminated can be removed from the resin film (support medium), and then an electric conducting layer (II) can be formed on the electric insulating layer by the plating method to produce a multilayered circuit board in the present invention. Moreover, in case of using a molded body laminated on a support medium composed of a metallic foil, the metallic foil laminated on the molded body (electric insulating layer) can be etched into desired wiring pattern by well-known etching method to make an electric conducting layer (II), which can result in manufacturing a multilayered circuit board in the present invention. In the present invention, the former method is preferable.

The method of manufacturing the multilayered circuit board of the present invention by plating or the like to form the electric conducting layer (II) on the electric insulating layer is described specifically as follows.

When the multilayered circuit board is manufactured, via hole which penetrates the electric insulating layer is usually formed at first to connect an each electric conducting layers in the multilayered circuit board before forming the electric conducting layer (II).

Via hole can be formed by a chemical treatment such as photolithography method, a physical treatment such as drill, laser, and plasma etching, or the like. Among these methods, the method using laser such as carbon dioxide gas laser, excimer laser and UV-YAG laser is preferred, since it can form finer via hole without deteriorating the properties of the electric insulating layer.

Then, to improve the adherence property with the electric conducting layer (II), the surface of the electric insulating layer may be oxidized to be roughened, and may be adjusted to a desired surface average roughness.

In the present invention, a surface average roughness Ra of electric insulating layer is preferably 0.05 μm or more and less than 0.3 μm, and more preferably 0.06 μm or more and 0.2 μm or less, and ten-points surface average roughness Rz JIS is preferably 0.3 μm or more and less than 4 μm, and more preferably 0.5 μm or more and 2 μm or less.

Here, Ra is a centerline average roughness shown in JIS B0601-2001, and ten-points surface average roughness Rz JIS is a ten-points average roughness shown in the attachment book 1 of JIS B0601-2001.

To oxidize a surface of an electric insulating layer, an oxidizing compound may be contact with the surface of the electric insulating layer.

Examples of the oxidizing compound include a well-known compound having oxidizing capability such as inorganic peroxide and organic peroxide. Inorganic peroxide or organic peroxide is preferably particularly employed from the viewpoint of the easiness to control an average surface roughness of the electric insulating layer. Examples of the inorganic peroxide include permanganate, chromic anhydride, dichromate, chromate, persulfate, active manganese dioxide, osmium tetroxide, hydrogen peroxide, periodate, ozone, and the like. Examples of the organic peroxide include dicumyl peroxide, octanoyl peroxide, m-chloroperbenzoic acid, acetyl hydroperoxide, and the like.

The method of oxidizing the surface of the electric insulating layer using the inorganic peroxide and the organic peroxide is not particularly limited. Examples of the method of oxidizing include a method comprising the successive steps of: dissolving the oxidizing compound to a solvent to prepare a solution of the oxidizing compound; and contacting the solution of the oxidizing compound with the surface of the electric insulating layer.

The method of contacting the inorganic peroxide or organic peroxide, or the solution thereof with a surface of the electric insulating layer is not particularly limited. Examples of the method of contacting may include a dip method in which the electric insulating layer is immersed in the solution of the oxidizing compound; a puddling method in which the solution of the oxidizing compound is put on the electric insulating layer by using a surface tensity; a spray method in which the solution of the oxidizing compound is sprayed on a substrate; and the like.

The temperature and time for contacting these inorganic peroxide or organic peroxide with a surface of the electric insulating layer may be set arbitrarily in consideration of density of the peroxide, type of the peroxide, contacting method of the peroxide, or the like. The above-mentioned temperature ranges usually from 10 to 250° C., and preferably from 20 to 180° C., and the above-mentioned time ranges usually from 0.5 to 60 minutes, and preferably from 1 to 30 minutes.

The examples of the oxidation treatment using a gas include reverse sputtering, corona discharge treatment, plasma treatment which generates radicals and ions from the gas, and the like. Examples of the gas include air, oxygen, nitrogen, argon, steam, carbon disulfide, carbon tetrachloride, and the like. An oxidation treatment is carried out under reduced pressure if the gas for the oxidation treatment is in liquid state at a treatment temperature under a normal pressure and in gas state at the treatment temperature under reduced pressure. Moreover, the oxidation treatment performs after pressurizing the gas to a pressure where generating of radicals or ions are possible, if the gas for the oxidation treatment is in gas state at a treatment temperature under the treatment pressure.

The temperature and time for contact a plasma with a surface of the electric insulating layer may be set in consideration of type of the gas, flow rate of the gas, or the like. The temperature for contact ranges usually from 10 to 250° C., and preferably from 20 to 180° C.; and the time for contact ranges usually from 0.5 to 60 minutes, and preferably from 1 to 30 minutes.

Moreover, a polymer or an inorganic filler soluble in the solution of oxidizing compound are preferably included in the curable resin composition which composes an electric insulating layer, in case of oxidation of a surface of the electric insulating layer by using the solution of the oxidizing compound. Since the inorganic filler and the polymer (A) dissolve selectively after forming a minute sea-island structure, it becomes easy to control the surface roughness of the insulating layer within the above-mentioned range.

The examples of a polymer soluble in a solution of an oxidizing compound include, liquid epoxy resins, polyester resins, bismaleimide triazine resins, silicone resins, polymethylmethacrylate resins, crude rubbers, styrene based rubbers, isoprene based rubbers, butadiene based rubbers, nitrile based rubbers, ethylene based rubbers, propylene based rubbers, polyurethane rubbers, butyl rubbers, silicone rubbers, fluorine-containing rubbers, norbornene rubbers, ether based rubbers, and the like.

The amount of a polymer soluble in a solution of an oxidizing compound is not limited, and ranges usually from 1 to 30 parts by weight, preferably from 3 to 25 parts by weight, and more preferably from 4 to 20 parts by weight based on 100 parts by weight of alicyclic olefin polymer (A).

Examples of a inorganic filler soluble in a solution of an oxidizing compound include, calcium carbonate, magnesium carbonate, barium carbonate, zinc oxide, titanium oxide, magnesium oxide, magnesium silicate, calcium silicate, zirconium silicate, aluminum hydrate, magnesium hydroxide, aluminum hydroxide, barium sulphate, silica, talc, clay, and the like. Among them, calcium carbonate and silica are suitable to make a surface minutely roughened, since they are prepared easily as a minute particle, and are eluted easily in the filler solubility solution. These inorganic fillers may have been treated by a silane coupling agent or an organic acid such as stearic acid.

It is preferable that the added inorganic filler has non-electric conductivity which doesn't decrease a dielectric characteristic of the electric insulating layer. Moreover, a shape of the added inorganic filler is not particularly limited, the shape may be spheroidal, fibroid, plate-like, and the like. The shape is preferably fine powdery to obtain a minute rough surface.

An average particle diameter of inorganic filler used is usually 0.008 μm or more and less than 2 μm, preferably 0.01 μm or more and less than 1.5 μm, and particular preferably 0.02 μm or more and less than 1 μm. If the average particle diameter is too small, a uniform adhesion is not likely to be obtained at a large-scale substrate. If the average particle diameter is too large oppositely, a high density wiring pattern is not likely to be obtained since a large rough surface will be generated at an electric insulating layer.

The amount of the inorganic filler soluble in a solution of an oxidizing compound can be appropriately selected depending on a level of needed adhesion, ranges from 1 to 80 parts by weight, preferably from 3 to 60 parts by weight, and more preferably from 5 to 40 parts by weight based on 100 parts by weight of the polymer (A).

This polymer or inorganic filler soluble in the solution of an oxidizing compound may be a part of a flame retardant auxiliary, a heat stabilizer, a dielectric property adjuster, and a toughness agent which are arbitrarily added to curable resin composition used for the present invention.

After the oxidation treatment of the electric insulating layer, the surface of the electric insulating layer is usually washed with water to remove the oxidizing compound. When a material which cannot be washed only by water adheres, the surface of the electric insulating layer is washed further with a cleaning solution which can dissolve the material, or washed with water after converting the material into a soluble material by contacting the material with other compound. For example, when an alkaline aqueous solution such as potassium permanganate aqueous solution and sodium permanganate aqueous solution is contacted with the electric insulating layer, to remove the membrane of the generated manganese dioxide, the surface of the electric insulating layer can be washed with water after neutralization and reduction with an acidic aqueous solution such as compound liquid of hydroxyamine sulphate and sulfuric acid.

After oxidizing the electric insulating layer and adjusting the surface average roughness, the electric conducting layer (II) is formed on a surface of the electric insulating layer and an inner wall surface of via hole in the laminated body. A method of forming the electric conducting layer (II) is not especially limited, but the plating method is preferable from the viewpoint of forming an excellent electric conducting layer (II) in adhesion.

The procedure for forming the electric conducting layer (II) by the plating method is not particularly limited. For example, a method of building up a metallic layer by thickening plating after forming a thin metallic film on the electric insulating layer by plating or the like can be employed.

When nonelectrolytic plating is used to form a thin metallic film, it is general to put accelerans core such as silver, palladium, zinc or cobalt on the electric insulating layer before forming the thin metallic film on the surface of the electric insulating layer.

The method of putting the accelerans core on the electric insulating layer is not especially limited. For examples, there is a method comprising: immersion into a solution of chemical compound, salts, complex, or of metal such as silver, palladium, zinc and cobalt to water or organic solvent such as alcohol and chloroform, in a density of 0.001 to 10% by weight (the solution may comprise an acid, an alkali, a complexing agent, a reducing agent and the like, if necessary), and metal reduction.

A known autocatalystic electroless plating solution can be used as an electroless plating solution used in nonelectrolytic plating method. A type of metal, a type of reducing agent and a type of complexing agent in the plating solution, and concentration of hydrogen ions and dissolved oxygen level of the plating solution are not especially limited.

For examples, an electroless copper plating solution containing ammonium hypophosphite, hypophosphorous acid, ammonium borohydride, hydrazine, formalin or the like as reducing agent; an electroless nickel phosphorus plating solution containing sodium hypophosphite as reducing agent; an electroless nickel boron plating solution containing dimethylamine-borane as reducing agent; an electroless palladium plating solution; an electroless palladium phosphorus plating solution containing sodium hypophosphite as reducing agent; an electroless gold plating solution; an electroless silver plating solution; an electroless nickel cobalt phosphorus plating solution containing sodium hypophosphite as reducing agent; and the like can be employed as the electroless plating solution.

After forming the thin metallic film, a corrosion control can be done by contacting a corrosion proof agent with the surface of the substrate. Moreover, after the thin metallic film is formed, the thin metallic film can be heated for the adhesion improvement or the like. The heating temperature ranges usually from 50 to 350° C., and preferably from 80 to 250° C.

The heating may be carried out under the pressurized condition. For example, the method of pressurizing at this time includes a method of using the physical pressurizing means such as a heat press machine and a pressurizing heating roll machine. The applied pressure ranges usually from 0.1 to 20 MPa, and preferably from 0.5 to 10 MPa. If the applied pressure is in the range, high adhesion of the thin metallic film and the electric insulating layer is secured.

A resist pattern for plating is formed on the thin metallic film obtained by the above-mentioned method. The metal layer is grown up on the resist pattern by the wet plating such as an electrolytic plating (thickening plating). Then, the resist is removed. The metal layer is etched like the pattern to form an electric conducting layer (II). As the result, the electric conducting layer (II) obtained by this method is usually composed of the patterned metallic film and plated layer on the thin metallic film.

Using of a multilayered circuit board which is obtained by the above-mentioned method as a new substrate for the laminated body can produce further multilayered by repeating the above-mentioned steps of an electric insulating layer formation and an electric conducting layer (II) formation, which can give an intended multilayered circuit board.

The multilayered circuit board in the present invention is excellent in the adhesion of electric insulating layer and electric conducting layer (II). A peeling strength between the electric conducting layer (II) and the electric insulating layer of the multilayered circuit board in the present invention measured in accordance with JIS C6481-1996 is usually 6 N/cm or more, and preferably 8 N/cm or more.

The multilayered circuit board in the present invention is excellent in the cracking resistance. When the multilayered circuit board of the present invention is examined in accordance with an examination of Eriksen A (JIS 22247-2006), the distance (Eriksen value) between wrinkle presser surface and point of punch moved at the time when the crack occurs on the surface of the board is usually 4 mm or more, and preferably 5 mm or more.

Since the multilayered circuit board of the present invention has an excellent electrical property, it can be suitably used as a board for surface-mounted component, which includes a semiconductor element such as CPU and memory, and the like in an electronics device such as computer, cellular phones, and the like as described later.

### 7) Electronics Device

An electronic device of the present invention is characterized in comprising the above-mentioned multilayered circuit board of the present invention. Examples of the electronic devices of the present invention include a cellular phone, a PHS, notebook-sized personal computer, PDA (portable information terminal), a portable video phone, a personal computer, a super computer, a server, a router, a liquid crystal projector, an engineering workstation (EWS), a pager, a word processor, a television, a video tape recorder of the viewfinder type or the monitor direct view type, an electronic notebook, an electronic desk calculator, a car navigation device, a POS terminal, a device comprising a touch panel, and the like. Since an electronics device of the present invention comprises the multilayered circuit board of the present invention, the electronics device is highly-efficient and high-quality.

### EXAMPLES

The present invention will be described more specifically with reference to EXAMPLES in the following. However, the present invention is not limited to EXAMPLES. In the following EXAMPLES and COMPARATIVE EXAMPLES, “parts” or “%” is by weight unless otherwise specified.

The definition and the measuring method of an each characteristic are as follows.

(1) Number Average Molecular Weight (Mn), Weight Average Molecular Weight (Mw) and of Polymer

Mn and Mw were measured by gel permeation chromatography (GPC) with toluene (tetrahydrofuran was used when a polymer didn't dissolve to the toluene) as a developing solvent, as a polystyrene conversion value.

(2) Hydrogenation Ratio of Polymer

Hydrogenation Ratio means the ratio of the molar number of hydrogenated unsaturated bonds relative to the molar number of unsaturated bonds having existed in polymer before hydrogenation, and was measured by ¹H-NMR spectrum.

(3) Acid Anhydride Group Content of Polymer

Acid anhydride group content means the ratio of the number of moles of acid anhydride group relative to the number of total monomer units in polymer, and was measured by ¹H-NMR spectrum.

(4) Glass Transition Temperature of Polymer (Tg)

Tg was measured by the differential scanning calorimetry method (DSC method) at the heating rate of 10° C./min.

(5) Volume Resistivity of Polymer

Volume resistivity was measured on the basis of ASTM D257-93.

(6) Phosphorus Element Content of a Curable Resin Composition

A curable resin composition was spread on the polyethylene naphthalate film (300 mm in width, 300 mm in length, 40 μm in thickness, Surface average roughness Ra 0.08 μm) by using the die coater. Then, a film (Thickness 35 μm) was obtained on the support medium by drying for 10 minutes at 80° C. under the nitrogen atmosphere. The fragment is cut out from this film peeled off the support medium, a volatile matter content was removed from the fragment by the vacuum drying at 100° C., and weight (=amount of dry solid) thereof was measured. The fragment after the gravimetry was burnt by oxygen flask combustion method in accordance with JIS K6233-1:96, and the elemental phosphorus in the fragment was captured to aqueous solution as a phosphoric ion. This aqueous solution was measured in the ion chromatography analysis in accordance with JIS K0127:01 and the content of the phosphorus element was required. The phosphorus element content was calculated based on the weight of dry solid of the fragment before burning.

(7) Linear Coefficient of Expansion

The film with support medium, which was obtained as well as the above-mentioned (6), was laminated to the one side of the rolled copper foil of 75 μm in thickness in the state that the film is inside. The support medium was only peeled off to leave the film, the film was heated under nitrogen atmosphere at 60° C. for 30 minutes and then at 170° C. for 60 minutes to be cured. Then, the rolled copper foil was etched with a mixed solution of copper chloride and hydrochloric acid to be wholly removed, which results in providing the cured film (cured sheet). A fragment being 5.95 mm in width, 15.4 mm in length, and 30 μm in thickness was cut out from the obtained cured sheet, and the linear expansion coefficient was measured by thermogravimetric/differential thermal simultaneous measuring equipment (TMA/SDTA840: manufactured by Mettler Toledo International Inc.) under the condition that the distance between fulcrums was 10 mm and temperature rise speed was 10° C./min., and was judged by a standard listed below.

⊚: The value of the linear coefficient of expansion was less than 25 ppm/° C.

◯: The value of the linear coefficient of expansion was 25 ppm/° C. or more and less than 40 ppm/° C.

Δ: The value of the linear coefficient of expansion was 40 ppm/° C. or more and less than 55 ppm/° C.

x: The value of the linear coefficient of expansion was 55 ppm/° C. or more.

(8) Electrical Property (Relative Permittivity and Dielectric Tangent)

The fragment being 2.6 mm in width, 80 mm in length, and 30 μm in thickness was cut out from the cured sheet obtained as well as the above-mentioned (7), and the relative permittivity and the dielectric tangent were measured by a cavity resonator perturbation method permittivity measuring equipment at 10 GHz, and was judged by a standard listed below.

◯: The dielectric tangent was less than 0.01, and the relative permittivity was less than 2.8.

Δ: The dielectric tangent was less than 0.01, and the relative permittivity was 2.8 or more.

x: The dielectric tangent was 0.01 or more.

(9) Adhesion of Electric Conducting Layer

The peeling strength between the electric conducting layer and the electric insulating layer was measured in accordance with JIS C6481-1996, and was judged by a standard listed below.

◯: The average peeling strength exceeded 7 N/cm.

Δ: The average peeling strength exceeded 5 N/cm, and was 7 N/cm or less.

x: The average peeling strength was 5 N/cm or less.

(10) Patterning Property

The wiring pattern having 50 lines, wiring width of 30 μm; distance between wiring of 30 μm, and wiring length of 50 mm was formed, and was judged by a standard listed below.

◯: There was not disorder in shape and no loss.

Δ: There was disorder in shape in the wiring pattern but no loss.

x: There was a loss in the wiring pattern.

(11) Cracking Resistance

By using a test piece Type 2 in accordance with an examination of Eriksen A (JIS Z2247-2006) prepared from a multilayered circuit board after plating pretreatment, the distance (Eriksen value) between wrinkle presser surface and point of punch moved at the time when the crack occurs on the surface of the board was measured and was judged on the basis of the result by a standard listed below.

◯: The Eriksen value was 5 mm or more.

Δ: The Eriksen value was 4 mm or more, and less than 5 mm.

x: The Eriksen value was less than 4 mm.

(12) Flame Retardancy

A reed-shaped specimen being 13 mm in width and 100 mm in length was prepared by cutting the inner layer board (Before forming via hole) on which an electric insulating layer was formed. This specimen was exposed to the flame of the Bunsen burner based on the method of the UL94V vertical firing examination. The flame was removed at once after exposure to flame for 10 seconds, and then a time that the specimen had burnt was measured. When flame of the specimen disappeared, the specimen was exposed to flame, at once, for 10 seconds again. The flame was removed at once after the second exposure to flame, and a time that the specimen had burnt was measured. The flame retardancy was judged on the basis of the result by a standard listed below.

◯: The total of the burning time after the first exposure and the burning time after the second exposure was within 20 seconds.

Δ: The total of the burning time after the first exposure and the burning time after the second exposure was longer than 20 seconds and 30 seconds or shorter.

x: The total of the burning time after the first exposure and the burning time after the second exposure was longer than 30 seconds, or the burning area gets to the upper part of the specimen.

(13) Moisture Resistance

Fragment being 30 mm in length, 30 mm in width, and 30 μm in thickness was cut out from the cured sheet obtained as well as the above-mentioned (7), and the fragment was left for 24 hours under the environment (unsaturated mode) at a temperature of 121° C. and a humidity of 100%. And then the surface of the fragment was inspected in appearance by a photon microscope, and the moisture resistance was judged on the basis of the result by a standard listed below.

◯: A particulate precipitate was not observed on the electric insulating layer being the surface of the fragment.

Δ: A particulate precipitate of less than 1 μm was observed on the surface of the fragment.

x: A particulate precipitate of 1 μm or more was observed on the surface of the fragment.

### Producing Example 1

First, 1-butene was added as a molecular weight modifier, and 8-ethyl-tetracyclo[4.4.0.1^{2,5}.1^{7,10}]dodeca-3-ene (hereinafter abbreviated to “ETD”) was ring opening polymerized, and then hydrogenation was done to obtain a hydrogenation product of ETD ring opening polymer. The obtained hydrogenation product of ETD ring opening polymer had Mn of 31,500, Mw of 56,200, and Tg of 140° C. Moreover, the hydrogenation ratio was 99% or more. Then, 100 parts of the hydrogenation product of ETD ring opening polymer, 45 parts of maleic anhydride, and 5 parts of dicumyl peroxide were dissolved to 250 parts of t-butyl benzene, and a graft reaction was carried out for 6 hours at 140° C. The reaction solution was poured into 1,000 parts of iso-propyl alcohol to precipitate a reaction product. The precipitate was dried by the vacuum for 20 hours at 100° C. to obtain an acid anhydride group-containing polymer (a) modified by the maleic anhydride. The acid anhydride group-containing polymer (a) had Mn of 33,800, Mw of 69,000, and Tg of 171° C. Moreover, a maleic anhydride residue content of the polymer (a) was 29 mol %, and a volume resistivity of the polymer (a) was 1×10¹⁴ Ω·cm or more. The results are shown in Table 1.

[Table 1]

TABLE 1

| | | | | Acid anhydride group- | | | | | |
|---|---|---|---|---|---|---|---|---|---|
| | hydrogenation product | | | containing polymer | | | | | |
| | of ring opening polymer | | | | | | | maleic anhydride | volume |
| | | | Tg | | | | Tg | residue content | resistivity |
| | Mn | Mw | [° C.] | | Mn | Mw | [° C.] | [mol %] | [Ω · cm] |
| PRODUCING | 31,500 | 56,200 | 140 | a | 33,800 | 69,000 | 171 | 29 | 1 × 10¹⁴ |
| EXAMPLE 1 | | | | | | | | | or more |
| PRODUCING | 43,300 | 95,500 | 140 | b | 45,600 | 97,900 | 172 | 29 | 1 × 10¹⁴ |
| EXAMPLE 2 | | | | | | | | | or more |
| PRODUCING | 124,000 | 325,000 | 150 | c | 134,000 | 343,800 | 175 | 29 | 1 × 10¹⁴ |
| EXAMPLE 3 | | | | | | | | | or more |
| PRODUCING | 4,000 | 5,900 | 108 | d | 4,200 | 6,000 | 109 | 29 | 1 × 10¹⁴ |
| EXAMPLE 4 | | | | | | | | | or more |
| PRODUCING | 31,500 | 56,200 | 140 | e | 33,200 | 68,700 | 170 | 89 | 1 × 10¹⁴ |
| EXAMPLE 5 | | | | | | | | | or more |
| PRODUCING | 31,500 | 56,000 | 140 | f | 33,600 | 68,500 | 171 | 25 | 1 × 10¹⁴ |
| EXAMPLE 6 | | | | | | | | | or more |
| PRODUCING | 31,500 | 56,200 | 140 | g | 33,300 | 68,800 | 171 | 2 | 1 × 10¹⁴ |
| EXAMPLE 7 | | | | | | | | | or more |

### Producing Example 2

A hydrogenation product of ETD ring opening polymer having Mn of 43,300, Mw of 95,500, and Tg of 140° C. was obtained in the same manner as in PRODUCING EXAMPLE 1, except that the amount of 1-butene was decreased. The hydrogenation ratio of the hydrogenation product of ring opening polymer was 99% or more. An acid anhydride group-containing polymer (b) was obtained by the graft reaction in the same manner as in PRODUCING EXAMPLE 1, except that the obtained hydrogenation product of ETD ring opening polymerization product was used. The results of measuring an each characteristic of the acid anhydride group-containing polymer (b) are shown in Table 1.

### Producing Example 3

A hydrogenation product of ETD ring opening polymer having Mn of 124,000, Mw of 325,000, and Tg of 150° C. was obtained in the same manner as in PRODUCING EXAMPLE 1, except that 1-butene was not added. The hydrogenation ratio of the hydrogenation product of ring opening polymer was 99% or more. Then, 100 parts of the hydrogenation product of ETD ring opening polymer, 45 parts of maleic anhydride, and 7 parts of dicumyl peroxide were dissolved to 500 parts of t-butyl benzene, and graft reaction was carried out for 6 hours at 140° C. Then, an acid anhydride group-containing polymer (c) was obtained in the same manner as in PRODUCING EXAMPLE 1. The results of measuring an each characteristic of the acid anhydride group-containing polymer (c) are shown in Table 1.

### Producing Example 4

A hydrogenation product of ETD ring opening polymer having Mn of 4,000, Mw of 5,900, and Tg of 108° C. was obtained in the same manner as in PRODUCING EXAMPLE 1, except that the amount of 1-butene was increased. The hydrogenation ratio of the hydrogenation product of ring opening polymer was 99% or more, an acid anhydride group-containing polymer (d) was obtained by the graft reaction in the same manner as in PRODUCING EXAMPLE 1 except that the obtained hydrogenation product of ETD ring opening polymer was used. The results of measuring an each characteristic of acid anhydride group-containing polymer (d) are shown in Table 1.

### Producing Examples 5 to 7

Acid anhydride group-containing polymers (e), (f), and (g) were obtained in the same manner as in PRODUCING EXAMPLE 1, except that the amount of the maleic anhydride used in the graft reaction was respectively adjusted to 142 parts, 40 parts, or 3 parts. The results of measuring an each characteristic of the acid anhydride group-containing polymers (e), (f), and (g) are shown in Table 1.

### Example 1

To obtain a resin solution, 100 parts of the acid anhydride group-containing polymer (a) as an alicyclic olefin polymer (A) component, 40 parts of bisphenol A bis(propylene glycol glycidyl ether) ether (Brand name: “ADEKA RESIN EP4000S” manufactured by ADEKA Corporation) as curing agent (B) component, 3 parts of 2-[2-hydroxy-3,5-bis(α,α-dimethyl benzyl)phenyl]benzotriazole as a laser processability improver, 0.1 part of 1-benzyl-2-phenylimidazole as a curing accelerator, 5 parts of “RIKACID TMTA-C” (manufactured by New Japan Chemical co., ltd.) as an acid anhydride, and 5 parts of a liquid polybutadiene (“Nisseki polybutadiene B-1000”: manufactured by Nippon Petrochemicals Co., Ltd.) as a polymer soluble in an oxidation treatment solution were dissolved to a mixed solvent of 215 parts of xylene and 54 parts of cyclopentanone.

To obtain a mixed solution, 40 parts of a condensed phosphate ester flame retarder “PX200” (manufactured by Daihachi Chemical Industry Co., Ltd.) was dissolved to a mixed solvent of 80 parts of xylene and 20 parts of cyclopentanone.

To obtain a flame retarder slurry, 50 parts of melamine polyphosphate flame retarder “PMP200” (manufactured by Nissan Chemical Industries, Ltd.) was dispersed to the mixed solvent of 80 parts of xylene and 20 parts of cyclopentanone by using a planetary mill.

The mixed solution and the flame retarder slurry were added to and mixed with the resin solution so as to be a ratio of PX200 and PMP200 as shown in Table 2, which resulted in obtaining a curable resin composition.

The curable resin composition was spread by using the die coater on a polyethylene naphthalate film having length of 300 mm, width of 300 mm, thickness of 40 μm, and surface average roughness Ra of 0.08 μm (support medium: “Teonex” manufactured by Teijin DuPont Films Japan Limited). And then, the drying under the nitrogen atmosphere at 80° C. for 10 minutes was carried out to obtain a film of 35 μm in thickness on the support medium. The phosphorus element content in the obtained film was measured, and the results are shown in Table 2.

A board (inner layer board) having a core substrate and an electric conducting layer on the both surface of the core substrate was prepared, in which the electric conducting layer had a surface which was micro-etched by contacting an organic acid, and the electric conducting layer was composed of copper wirings having width of 50 μm, interval of 50 μm and thickness of 18 μm, and in which the core substrate was obtained by impregnating glass fibers with a varnish comprising glass fillers and halogen-free epoxy resins, and the core substrate had thickness of 0.8 mm, length of 50 mm and width of 150 mm.

The film with support medium was cut out into the size of 150 mm length×150 mm width. The cut film with support medium was overlapped with both sides of the inner layer board so that the film was inside and the support medium was outside. This was thermo compression bonded for 300 seconds under a reduced pressure of 200 Pa, at a temperature of 120° C. and a compression force of 1.0 MPa by using a vacuum laminator equipped with two pressing plates made of heat-resisting rubber at the top and bottom respectively (first pressing step). In addition, this was thermo compression bonded for 300 seconds under a reduced pressure of 200 Pa, at a temperature of 140° C. and a compression force of 1.0 MPa by using a vacuum laminator equipped with two pressing plates made of heat-resisting rubber covered with metallic pressing plate at the top and bottom respectively (second pressing step). Then, the support medium was peeled off to obtain a multilayer substrate composed of a laminate of the layer of the uncured resin molded body and the inner layer board.

The multilayer substrate was immersed in 1.0% aqueous solution of the 1-(2-aminoethyl)-2-methyl imidazole at 30° C. for 10 minutes and then was immersed in water at 25° C. for 1 minute. An excess solution was removed with an air knife. The resin molded body was cured by being left at 170° C. for 60 minutes under the nitrogen atmosphere to form an electric insulating layer (cured product) on the inner layer board. The flame retardancy of the inner layer board with which the electric insulating layer was formed was evaluated. A via hole for interlayer connection of 30 μm in diameter was made in the electric insulating layer with the UV-YAG laser third harmonic to obtain a laminated body.

The laminated body having a via hole was immersed and shaken for 10 minutes at 70° C. in an aqueous solution comprising 60 g/liter in density of permanganic acid and 28 g/liter in density of sodium hydroxide. This laminated body was immersed and shaken for 1 minute in a water tank, and was immersed and shaken for 1 minute in another water tank to be washed. Subsequently, the laminated body was immersed at 25° C. for 5 minutes in an aqueous solution comprising 170 g/liter in density of hydroxylamine sulfate and 80 g/liter in density of sulfuric acid to be neutralized and reduced. The laminated body was washed with water.

Next, as a plating pretreatment, the laminated body after the water washing was immersed for 5 minutes in a palladium salt containing plating catalyst aqueous solution at 60° C. comprising 200 ml/liter of ALCUP ACTIVATOR MAT-1-A (made by the C. Uyemura & Co., Ltd.), 30 ml/liter of ALCUP ACTIVATOR MAT-1-B (made by the C. Uyemura & Co., Ltd.), and 0.35 g/liter of sodium hydroxide. Then, this laminated body was immersed and shaken for 1 minute in a water tank, and was immersed and shaken for 1 minute in another water tank to be washed. This laminated body was immersed for 3 minutes at 35° C. in a solution comprising 20 ml/liter of ALCUP REDUCER MAB-4-A (made by C. Uyemura & Co., Ltd.) and 200 ml/liter of ALCUP REDUCER MAB-4-B (made by C. Uyemura & Co., Ltd.) to reduce the plating catalyst. Thus, the laminated body adsorbing the plating catalyst and previously-treated for plating was obtained. As to the obtained laminated body, cracking resistance or the like was measured. The evaluation results are shown in Table 2.

Next, The laminated body previously-treated for plating was immersed at 36° C. for 5 minutes in aqueous solution comprising 100 ml/liter of THRU-CUP PSY-1A (made by C. Uyemura & Co., Ltd.), 40 ml/liter of THRU-CUP PSY-1B (made by C. Uyemura & CO., Ltd.), and 0.2 moles/liter of formalin, while blowing air into the aqueous solution, by which the electroless copper plating treatment was carried out to form a metallic thin film layer on the laminated body. In addition, The laminated body having the metallic thin film layer formed by the electroless plating treatment was immersed and shaken for 1 minute in a water tank, and then was immersed and shaken for 1 minute in another water tank to be washed. Drying and a rustproof treatment were carried out, which resulted in giving a multilayered circuit board which had the electroless plating film.

A commercially available photo sensitive dry film resist was applied on the surface of the multilayered circuit board subjected to the rustproof treatment by thermo compression bonding. A mask having a pattern corresponding to the pattern for adhesion evaluation was put on the dry film resist. This was exposed and developed to obtain a resist pattern. Then, the multilayered circuit board was immersed in 100 g/liter aqueous solution of sulfuric acid for 1 minute at 25° C. to remove the rust retardant. An electrolytic copper plating was applied to form an electrolytic plated copper film having a thickness of 18 μm on the non-formation area of the resist. The resist pattern was stripped and removed with a stripping liquid. An etching treatment was carried out with a mixed aqueous solution of cupric chloride and hydrochloric acid to form a wiring pattern composed of the thin metallic film and the electrolytic plated copper film. As a result, a double sided multilayered circuit board (a) with two layers of the wiring pattern was obtained. Finally, an annealing treatment was carried out at 170° C. for 30 minutes, obtaining a multilayered printed wiring board. The obtained multilayered circuit board (a) was estimated to determine patterning properties, cracking resistance, or the like. The evaluation results are shown in Table 2.

[Table 2]

TABLE 2

| | | | Ex. 1 | Ex. 2 | Ex. 3 | Ex. 4 | Ex. 5 | Ex. 6 | Ex. 7 |
|---|---|---|---|---|---|---|---|---|---|
| resin | Acid | a | 100 | 100 | 100 | 100 | 100 | | |
| composition | anhydride | b | | | | | | 100 | |
| | group- | c | | | | | | | 100 |
| | contaning | | | | | | | | |
| | resin | | | | | | | | |
| | [parts] | | | | | | | | |
| | flame | PMP200 | 20 | 20 | 45 | 10 | 20 | 20 | 20 |
| | retarder | PX200 | 20 | 20 | 5 | 40 | 20 | 20 | 20 |
| | [parts] | | | | | | | | |
| | Filler | silica | 0 | 0 | 0 | 0 | 30 | 0 | 0 |
| | [parts] | filler | | | | | | | |

| | | | | | | | |
|---|---|---|---|---|---|---|---|
| Phosphorus element | 2.03 | 2.03 | 2.57 | 2.29 | 1.76 | 2.03 | 2.03 |
| content (%) | | | | | | | |
| fibrous substrate | nil | exist | nil | nil | nil | nil | nil |
| Linear expansion | ◯ | ⊚ | ◯ | ◯ | ◯ | ◯ | ◯ |
| coefficient | | | | | | | |
| electrical property | ◯ | ◯ | ◯ | ◯ | ◯ | ◯ | ◯ |
| adhesion | ◯ | ◯ | Δ | Δ | ◯ | ◯ | Δ |
| patterning property | ◯ | ◯ | ◯ | ◯ | ◯ | ◯ | Δ |
| cracking resistance | ◯ | ◯ | ◯ | ◯ | ◯ | ◯ | Δ |
| flame retardancy | Δ | ◯ | Δ | Δ | Δ | Δ | Δ |
| moisture resistance | ◯ | ◯ | Δ | Δ | ◯ | ◯ | ◯ |

(note)
PX200; condensed phosphate ester flame retarder (manufactured by Daihachi Chemical Industry Co., Ltd.)
PMP200; melamine polyphosphate flame retarder (manufactured by Nissan Chemical Industries, Ltd.)

### Example 2

A nonwoven cloth having length of 250 mm, width of 250 mm, thickness of 35 μm and weight per unit area is 22 g/m², (“VECRUS MBEK22CXSP”: manufactured by Kuraray co., Ltd.) made of a liquid crystalline polymer composed of wholly aromatic polyester was set up on a polyethylene naphthalate film having length of 300 mm, width of 300 mm, thickness of 40 μm and surface average roughness Ra of 0.08 μm (support medium). The curable resin composition obtained in EXAMPLE 1 was spread and soaked on the liquid crystalline polymer nonwoven cloth. It was dried for 10 minutes at 80° C. under the nitrogen atmosphere to obtain a composite body containing 60% of the liquid crystalline polymer and having a thickness of 45 μm on the support medium. A multilayered circuit board was obtained in the same manner as in EXAMPLE 1, except that the composite body with the support medium was used in place of the film with the support medium. As to the items similar to EXAMPLE 1, the examinations and evaluations were carried out. The results are shown in Table 2.

### Example 3

A multilayered circuit board was obtained in the same manner as in EXAMPLE 1, except using a curable resin composition which was obtained by adding and mixing the mixed solution and the flame retarder slurry to the resin solution so as to be 5 parts of PX200 and 45 parts of PMP200. As to the items similar to EXAMPLE 1, the examinations and evaluations were carried out. The results are shown in Table 2.

### Example 4

A multilayered circuit board was obtained in the same manner as in EXAMPLE 1, except using a curable resin composition which was obtained by adding and mixing the mixed solution and the flame retarder slurry to the resin solution so as to be 40 parts of PX200 and 10 parts of PMP200. As to the items similar to EXAMPLE 1, the examinations and evaluations were carried out. The results are shown in Table 2.

### Example 5

A multilayered circuit board was obtained in the same manner as in EXAMPLE 1, except using a curable resin composition which was obtained by adding and mixing the mixed solution, the flame retarder slurry, and 30 parts of a silica filler (“Admafine Silica SC-5050” made by Admatechs Co., Ltd.) to the resin solution so as to be 20 parts of PX200 and 20 parts of PMP200. As to the items similar to EXAMPLE 1, the examinations and evaluations were carried out. The results are shown in Table 2.

### Example 6 to 7

A multilayered circuit board was obtained in the same manner as in EXAMPLE 1, except that acid anhydride group-containing polymer (b) or (c) shown in Table 2 was used in place of the acid anhydride group-containing polymer (a) used in EXAMPLE 1. As to the items similar to EXAMPLE 1, the examinations and evaluations were carried out. The results are shown in Table 2.

### Example 8

A multilayered circuit board was obtained in the same manner as in EXAMPLE 1, except that acid anhydride group-containing polymer (d) was used in place of the acid anhydride group-containing polymer (a) used in EXAMPLE 1. As to the items similar to EXAMPLE 1, the examinations and evaluations were carried out. The results are shown in Table 3.

### Example 9

A multilayered circuit board was obtained in the same manner as in EXAMPLE 1, except that acid anhydride group-containing polymer (e) was used in place of the acid anhydride group-containing polymer (a) used in EXAMPLE 1, and the amount of bisphenol A bis(propylene glycol glycidyl ether) ether was changed to 100 parts so as to make an equivalent ratio of acid anhydride and epoxy same as in EXAMPLE 1. As to the items similar to EXAMPLE 1, the examinations and evaluations were carried out. The results are shown in Table 3.

### Example 10

A multilayered circuit board was obtained in the same manner as in EXAMPLE 1, except that acid anhydride group-containing polymer (f) was used in place of the acid anhydride group-containing polymer (a) used in EXAMPLE 1, and the amount of bisphenol A bis(propylene glycol glycidyl ether) ether was changed to 36 parts so as to make an equivalent ratio of acid anhydride and epoxy same as in EXAMPLE 1. As to the items similar to EXAMPLE 1, the examinations and evaluations were carried out. The results are shown in Table 3.

### Example 11

A multilayered circuit board was obtained in the same manner as in EXAMPLE 1, except that acid anhydride group-containing polymer (g) was used in place of the acid anhydride group-containing polymer (a) used in EXAMPLE 1, and the amount of bisphenol A bis(propylene glycol glycidyl ether) ether was changed to 8 parts so as to make an equivalent ratio of acid anhydride and epoxy same as in EXAMPLE 1. As to the items similar to EXAMPLE 1, the examinations and evaluations were carried out. The results are shown in Table 3.

### Example 12

A multilayered circuit board was obtained in the same manner as in EXAMPLE 3, except that the amount of PX200 was changed to 0.5 parts. As to the items similar to EXAMPLE 1, the examinations and evaluations were carried out. The results are shown in Table 3.

### Example 13

A multilayered circuit board was obtained in the same manner as in EXAMPLE 1, except that the amount of PMP200 was changed to 30 parts. As to the items similar to EXAMPLE 1, the examinations and evaluations were carried out. The results are shown in Table 3.

[Table 3]

TABLE 3

| | | | Ex. 8 | Ex. 9 | Ex. 10 | Ex. 11 | Ex. 12 | Ex. 13 |
|---|---|---|---|---|---|---|---|---|
| resin | Acid | a | | | | | 100 | 100 |
| composition | anhydride | d | 100 | | | | | |
| | group- | e | | 100 | | | | |
| | contaning | f | | | 100 | | | |
| | resin | g | | | | 100 | | |
| | [parts] | | | | | | | |
| | flame | PMP200 | 20 | 20 | 20 | 20 | 45 | 30 |
| | retarder | PX200 | 20 | 20 | 20 | 20 | 0.5 | 20 |
| | [parts] | | | | | | | |
| | filler | silica | 0 | 0 | 0 | 0 | 0 | 0 |
| | [parts] | filler | | | | | | |

| | | | | | | |
|---|---|---|---|---|---|---|
| Phosphorus element | 2.03 | 1.55 | 2.07 | 2.43 | 2.42 | 2.45 |
| content (%) | | | | | | |
| fibrous substrate | nil | nil | nil | nil | nil | nil |
| Linear expansion | ◯ | ◯ | ◯ | ◯ | ◯ | ◯ |
| coefficient | | | | | | |
| electrical property | ◯ | Δ | ◯ | Δ | ◯ | ◯ |
| adhesion | Δ | Δ | ◯ | Δ | Δ | Δ |
| patterning property | Δ | ◯ | ◯ | ◯ | ◯ | ◯ |
| cracking resistance | Δ | Δ | ◯ | Δ | ◯ | ◯ |
| flame retardancy | Δ | Δ | Δ | Δ | Δ | Δ |
| moisture resistance | ◯ | ◯ | ◯ | ◯ | Δ | Δ |

(note)
PX200; condensed phosphate ester flame retarder (manufactured by Daihachi Chemical Industry Co., Ltd.)
PMP200; melamine polyphosphate flame retarder (manufactured by Nissan Chemical Industries, Ltd.)

### Producing Example 8

First, 1-butene was added as a molecular weight modifier, and 70 parts of 8-ethyl-tetracyclo[4.4.0.1^{2,5}.1^{7,10}]dodeca-3-ene (hereinafter abbreviated to “ETD” and 30 parts of bicyclo[2.2.1]hept-2-ene-5,6-dicarboxylic anhydride were ring opening polymerized. And then hydrogenation was conducted to obtain a hydrogenation product of the ring opening polymer. The obtained hydrogenation product of the ring opening polymer (acid anhydride group-containing polymer h) has Mn of 23,000, Mw of 50,000, and Tg of 142° C. Moreover, the hydrogenation ratio was 99% or more.

Since the residual monomer was inappreciable by gas chromatography, the conversion ratio of polymerization was substantially judged to be 100%. Therefore, the content of acid anhydride group corresponds to the amount of bicyclo[2.2.1]hept-2-ene-5,6-dicarboxylic anhydride used, and was calculated with 32.7 mole %.

### Example 14

To 400 parts of xylene, 100 parts of the hydrogenation product of ring opening polymer obtained in PRODUCING EXAMPLE 8, 35 parts of hydrogenated bisphenol A type (The brand name: “YX8000” Japan Epoxy Resins Co., Ltd.) as a curing agent (B) component, 3 parts of 2-[2-hydroxy-3,5-bis(α,α-dimethylbenzyl)phenyl]benzo-triazole as a laser processability improver, 0.5 part of 1-benzyl-2-phenylimidazole as a curing accelerator, and 10 parts of liquid polybutadiene (“Nisseki polybutadiene B-1000”: manufactured by the Nippon Petrochemicals Co., Ltd.) were dissolved to obtain a resin solution.

A multilayered circuit board was obtained in the same manner as in EXAMPLE 1, except using this resin solution. As to the items similar to EXAMPLE 1, the examinations and evaluations were conducted. The results are shown in Table 4.

### Example 15

A multilayered circuit board was obtained in the same manner as in EXAMPLE 2, except using the resin solution obtained in EXAMPLE 14. As to the items similar to EXAMPLE 1, the examinations and evaluations were carried out. The results are shown in Table 4.

### Comparative Examples 1-5

A multilayered circuit board was obtained in the same manner as in EXAMPLE 1, except using a curable resin composition which was obtained by adding a mixed solution and a flame retarder slurry to the resin solution obtained in EXAMPLE 1 so as to be the amount of PX200 and the amount of PMP200 as shown in Table 4. As to the items similar to EXAMPLE 1, the examinations and evaluations were carried out. The results are shown in Table 4.

[Table 4]

TABLE 4

| | | | | | Comp. | Comp. | Comp. | Comp. | Comp. |
|---|---|---|---|---|---|---|---|---|---|
| | | | Ex. 14 | Ex. 15 | Ex. 1 | Ex. 2 | Ex. 3 | Ex. 4 | Ex. 5 |
| resin | Acid | a | | | 100 | 100 | 100 | 100 | 100 |
| composition | anhydride | h | 100 | 100 | | | | | |
| | group- | | | | | | | | |
| | contaning | | | | | | | | |
| | resin | | | | | | | | |
| | [parts] | | | | | | | | |
| | flame | PMP200 | 20 | 20 | 55 | 10 | 10 | 30 | 5 |
| | retarder | PX200 | 20 | 20 | 5 | 45 | 5 | 0 | 30 |
| | [parts] | | | | | | | | |
| | filler | silica | 0 | 0 | 0 | 0 | 0 | 0 | 0 |
| | [parts] | filler | | | | | | | |

| | | | | | | | |
|---|---|---|---|---|---|---|---|
| Phosphorus element | 2.03 | 2.03 | 2.95 | 2.46 | 0.90 | 1.74 | 1.72 |
| content (%) | | | | | | | |
| fibrous substrate | nil | exist | nil | nil | nil | nil | nil |
| Linear expansion | ◯ | ⊚ | ◯ | ◯ | ◯ | ◯ | ◯ |
| coefficient | | | | | | | |
| electrical property | ◯ | ◯ | ◯ | ◯ | ◯ | ◯ | ◯ |
| adhesion | ◯ | ◯ | X | X | ◯ | ◯ | ◯ |
| patterning property | ◯ | ◯ | ◯ | ◯ | ◯ | ◯ | ◯ |
| cracking resistance | ◯ | ◯ | ◯ | ◯ | ◯ | ◯ | ◯ |
| flame retardancy | Δ | ◯ | Δ | Δ | X | X | X |
| moisture resistance | ◯ | ◯ | X | X | ◯ | Δ | Δ |

(note)
PX200; condensed phosphate ester flame retarder (manufactured by Daihachi Chemical Industry Co., Ltd.)
PMP200; melamine polyphosphate flame retarder (manufactured by Nissan Chemical Industries, Ltd.)

As shown in Table 2, Table 3 or Table 4, using of the composite body or molded body composed of the curable resin composition in the present invention gave the multilayered circuit boards, on which a high density wiring pattern was excellently formed, excelled in adhesion with the electric conducting layer, moisture resistance, flame retardancy, smooth surface, electrical property and cracking resistance, and had a low linear expansion coefficient (EXAMPLES 1 to 15).

Not only moisture resistance but also adhesion with the electric conducting layer were reduced when a salt (C) of a basic nitrogen-containing compound with phosphoric acid or condensed phosphate ester (D) was excessively added (COMPARATIVE EXAMPLE 1 or 2).

Oppositely, when a salt (C) of a basic nitrogen-containing compound with phosphoric acid or condensed phosphate ester (D) was inadequately added, the flame retardancy was insufficient (COMPARATIVE EXAMPLE 3 or 4).

In addition, when it was too little phosphorus, the flame retardancy was insufficient (COMPARATIVE EXAMPLE 5).

### INDUSTRIAL APPLICABILITY

A molded body and a composite body obtained from a curable resin composition in the present invention are excellent in a flame retardancy, an electric insulating property, and a cracking resistance, and hardly generates a harmful substance in burning.

A laminated body and a multilayered circuit board in the present invention have characteristics like a low-thermal expansion, and a high elastic modulus, and have high adhesion, even if the electric conducting layer is formed on a smooth electric insulating layer by the plating method, and have high reliability.

Since a multilayered circuit board in the present invention has an excellent electrical property, it can be suitably used as aboard for surface-mounted component, which includes a semiconductor element such as CPU and memory in electronics devices such as computer, and cellular phones.

1. A curable resin composition comprising:
100 parts by weight of an alicyclic olefin polymer (A);
from 1 to 100 parts by weight of a curing agent (B);
from 10 to 50 parts by weight of a salt (C) of a basic nitrogen-containing compound with a phosphoric acid; and
from 0.1 to 40 parts by weight of a condensed phosphate ester (D);
of which phosphorus element content is not less than 1.5% by weight based on dry solid.

2. The curable resin composition according to the claim 1, in which the salt (C) of a basic nitrogen-containing compound with a phosphoric acid is at least one compound selected from the group consisting of double salt of melamine-melam-melem polyphosphate, melamine polyphosphate, melam polyphosphate, melem polyphosphate, double salt of melamine-melam-melem orthophosphate, melamine orthophosphate, melam orthophosphate, melem orthophosphate, double salt of melamine-melam-melem pyrophosphate, melamine pyrophosphate, melam pyrophosphate, melem pyrophosphate, double salt of melamine-melam-melem metaphosphate, melamine metaphosphate, melam metaphosphate, and melem metaphosphate.

3. The curable resin composition according to the claim 1, in which the alicyclic olefin polymer (A) has carboxyl group and/or carboxylic acid anhydride group.

4. The curable resin composition according to claim 1, in which the alicyclic olefin polymer (A) has a volume resistivity by ASTM D257 of 1×10¹² Ω·cm or more.

5. The curable resin composition according to claim 1, in which the alicyclic olefin polymer (A) is from 10,000 to 250,000 in a weight average molecular weight (Mw).

6. The curable resin composition according to claim 1, in which the curing agent (B) is a multivalent epoxy compound.

7. The curable resin composition according to the claim 6, further comprising a curing accelerator.

8. The curable resin composition according to the claim 7, in which the curing accelerator is a tertiary amine compound.

9. The curable resin composition according to claim 1, further comprising a carboxylic acid anhydride having not less than two acid anhydride groups in a molecule.

10. A composite body comprising the curable resin composition according to claim 1, and a fibrous substrate.

11. The composite body according to the claim 10, in which the fibrous substrate is composed of continuous fiber of a liquid crystalline polymer.

12. The composite body according to the claim 11, in which the liquid crystalline polymer is a wholly aromatic polyester.

13. The composite body according to claim 10, in which the fibrous substrate is from 3 to 55 g/m² in weight per unit area.

14. The composite body according to claim 10, of which shape is a film or sheet.

15. A method for producing a composite body comprising a curable resin composition and a fibrous substrate, comprising:
a step of impregnating the curable resin composition according to claim 1 into the fibrous substrate and
a step of drying the impregnated curable resin composition.

16. A molded body composed of a film or sheet made of the curable resin composition according to claim 1.

17. A molded body comprising a support medium and a coating of the curable resin composition according to claim 1 applied on the support medium.

18. A cured product obtained by curing the molded body according to the claim 16.

19. A cured product obtained by curing the composite body according claim 10.

20. A laminated body comprising:
a board having an electric conducting layer on the surface thereof, and
the cured product according to the claim 18 laminated on the board, as an electric insulating layer.

21. A method for producing a laminated body comprising steps of:
thermo-compression bonding the composite body according to claim 10 onto a board having an electric conducting layer on the surface thereof, and
curing the bonded composite body to make an electric insulating layer.

22. A method for producing a laminated body comprising steps of:
thermo-compression bonding the molded body according to the claim 16 onto a board having an electric conducting layer on the surface thereof, and
curing the bonded molded body to make an electric insulating layer.

23. A multilayered circuit board comprising:
the laminated body according to the claim 20, and
another electric conducting layer formed on the electric insulating layer of the laminated body.

24. An electronic equipment comprising the multilayered circuit board according to the claim 23.
